(19) United States
(12) Patent Application Publication
(10) Pub. No.: US 2013/0161568 A1
(43) Pub. Date: Jun. 27, 2013

(54) Anthra[2,3-b:7,6-b']dithiophene Derivatives and their Use as Organic Semiconductors

(71) Applicants: Changsheng Wang, Durham (GB); Steven Tierney, Southampton (GB); Mansoor D'Lavari, Bude (GB); William Mitchell, Chandler's Ford (GB); Nicolas BLouin, Southampton (GB)

(72) Inventors: Changsheng Wang, Durham (GB); Steven Tierney, Southampton (GB); Mansoor D'Lavari, Bude (GB); William Mitchell, Chandler's Ford (GB); Nicolas BLouin, Southampton (GB)

(73) Assignee: MERCK PATENT GESELLSCHAFT MIT BESCHRANKTER HAFTUNG, Darmstadt (DE)

(21) Appl. No.: 13/820,789

(22) PCT Filed: Aug. 12, 2011
(86) PCT No.: PCT/EP2011/004076

§ 371 Date: Mar. 5, 2013

(30) Foreign Application Priority Data
Sep. 10, 2010 (EP) 10 009 454.9

(51) Int. Cl. H01L 51/00

(52) U.S. Cl. CPC H01L 51/0094
USPC 252/500; 549/4

(57) ABSTRACT

The invention relates to novel anthra[2,3-b:7,6-b′]dithiophene derivatives, methods of their preparation, their use as semiconductors in organic electronic (OE) devices, and to OE devices comprising these derivatives.

### FIELD OF THE INVENTION

The invention relates to novel anthra[2,3-b:7,6-b′]dithiophene derivatives, methods of their preparation, their use as semiconductors in organic electronic (OE) devices, and to OE devices comprising these derivatives.

### BACKGROUND AND PRIOR ART

Organic semiconductors (OSCs) are expected to revolutionise the manufacturing process of the thin film field-effect transistors (TFTs) used for display technologies. Compared with the classical Si based field-effect transistor (FETs), organic TFTs can be fabricated much more cost-effectively by solution coating methods such as spin-coating, drop casting, dip-coating, and more efficiently, ink-jet printing. Solution processing of OSCs requires the molecular materials to be 1) soluble enough in non-toxic solvents; 2) stable in the solution state; 3) easy to crystallise when solvents are evaporated; and most importantly, 4) to provide high charge carrier mobilities with low off currents. In this context, trialkysilylethynyl substituted heteroacenes, particularly anthra[2,3-b:7,6-b′]dithiophenes (ADTs) as described for example in W02008/107089 A1, US2008/0128680 A1 and U.S. Pat. No. 7,385,221 B1 have shown to be a promising class of OSC materials. Notably, the fluorinated derivatives have shown hole mobility greater than 1 cm²/Vs (see M. M. Payne, S. R. Parkin, J. E. Anthony, C.-C. Kuo and T. N. Jackson, J. Am. Chem. Soc., 2005, 127 (14), 4986; S. Subramanian, S. K. Park, S. R. Parkin, V. Podzorov, T. N. Jackson, and J. E. Anthony, J. Am. Chem. Soc., 2008, 130(9), 2706-2707).

However, some major drawbacks remain for these materials, which include: 1) low temperature phase transition / melting point and 2) high charge mobility coupled with low solubility, which limits the solvents available for printing. 3) For future OTFT backplanes for OLED driving applications, which demand higher source and drain current, the mobility and processibility of currently available materials needs further improvement.

Therefore, there is still a need for OSC materials that show good electronic properties, especially high charge carrier mobility, good processibilty and high thermal and environmental stability, especially a high solubility in organic solvents.

The aim of the present invention is to provide new compounds for use as organic semiconducting materials that do not have the drawbacks of prior art materials as described above, and do especially show good processibility, good solubility in organic solvents, high melting points and high charge carrier mobility. Another aim of the invention was to extend the pool of organic semiconducting materials available to the expert. Other aims of the present invention are immediately evident to the expert from the following detailed description.

It was found that these aims can be achieved by providing compounds as claimed in the present invention, which are based on ADT or derivatives thereof comprising two silylethynyl solublising groups with different substituents on each of the Si atoms. Most importantly, by fine-tuning the size and polarity of the substituents on the Si atoms of the solublising silylethynyl groups, the solubility and the melting point of the materials can both be increased, compared with the symmetric analogues bearing the same number of solublising carbon atoms.

It was also found that OFET devices, which contain compounds according to the present invention as semiconductors, show good mobility and on/off ratio values, and can easily be prepared using solution deposition fabrication methods and printing techniques.

Such compounds have not been reported in the literature up to date.

WO 2009/155106 A1 discloses pentacene derivatives with unsymmetrically substituted silylethynyl groups. However, pentacene-based materials have two major drawbacks compared with ADT-based OSC materials. Firstly, the solutions of pentacenes exhibit significant photo instability. They can only survive for a limited time scale under inert gas atmosphere and in absence of UV/ambient light. Secondly, these materials generally suffer from lower melting point than comparable ADT analogues.

In contrast thereto, the materials of the present invention possess increased photostability, improved organic solvent solubility, and higher melting point than analogous compounds with symmetrically substituted silylethynyl groups, thereby yielding materials with improved thermal stability, as will be shown in the following specification and examples.

### SUMMARY OF THE INVENTION

The invention relates to compounds of formula I

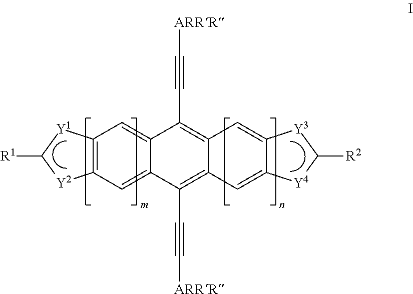

wherein the individual groups have the following meanings
one of Y¹ and Y² is —CH═ or ═CH— and the other is —X—,
one of Y³ and Y⁴ is —CH═ or ═CH— and the other is —X—,
X is —O—, —S—, —Se— or —NR^{x}—,
A is C or Si,
R¹ and R² independently of each other denote H, F, Cl, Br, I, straight chain, branched or cyclic alkyl with 1 to 20 C-atoms, which is unsubstituted or substituted by one or more groups L, and wherein one or more non-adjacent CH₂ groups are optionally replaced, in each case independently from one another, by —O—, —S—, —NR⁰—, —SiR⁰R⁰⁰—, —CY⁰═CY⁰⁰— or —C≡C— in such a manner that O and/or S atoms are not linked directly to one another, or denote aryl or heteroaryl with 4 to 20 ring atoms which is unsubstituted or substituted by one or more groups L,
R, R′, R″ are identical or different groups selected from the group consisting of H, a straight-chain, branched or cyclic alkyl or alkoxy group having 1 to 20 C atoms, a straight-chain, branched or cyclic alkenyl group having 2 to 20 C atoms, a straight-chain, branched or cyclic alkynyl group having 2 to 20 C atoms, a straight-chain, branched or cyclic alkylcarbonyl group having 2 to 20 C atoms, an aryl or heteroaryl group having 4 to 20 ring atoms, an arylalkyl or heteroarylalkyl group having 4 to 20 ring atoms, an aryloxy or heteroaryloxy group having 4 to 20 ring atoms, or an arylalkyloxy or heteroarylalkyloxy group having 4 to 20 ring atoms, wherein all the aforementioned groups are optionally substituted with one or more groups L,
L is selected from P-Sp-, F, Cl, Br, I, —OH, —CN, —NO₂, —NCO, —NCS, —OCN, —SCN, —C(═O)NR⁰R⁰⁰, —C(═O)X⁰, —C(═O)R⁰, —NR⁰R⁰⁰, C(═O)OH, optionally substituted aryl or heteroaryl having 4 to 20 ring atoms, or straight chain, branched or cyclic alkyl with 1 to 20, preferably 1 to 12 C atoms wherein one or more non-adjacent CH₂ groups are optionally replaced, in each case independently from one another, by —O—, —S—, —NR⁰—, —SiR⁰R⁰⁰—, —CY⁰═CY⁰⁰— or —C≡C— in such a manner that O and/or S atoms are not linked directly to one another and which is unsubstituted or substituted with one or more F or Cl atoms or OH groups,
P is a polymerisable group,
Sp is a spacer group or a single bond,
X⁰ is halogen,
R^{x} has one of the meanings given for R¹,
R⁰ and R⁰⁰ independently of each other denote H or alkyl with 1 to 20 C-atoms,
Y⁰ and Y⁰⁰ independently of each other denote H, F, Cl or CN,
m is 1 or 2,
n is 1 or 2,

wherein in at least one group ARR′R″ at least two of the substituents R, R′ and R″ are not identical.

The invention further relates to a formulation comprising one or more compounds of formula I and one or more solvents, preferably selected from organic solvents.

The invention further relates to an organic semiconducting formulation comprising one or more compounds of formula I, one or more organic binders, or precursors thereof, preferably having a permittivity ε at 1,000 Hz of 3.3 or less, and optionally one or more solvents.

The invention further relates to the use of compounds and formulations according to the present invention as charge transport, semiconducting, electrically conducting, photoconducting or light emitting material in an optical, electrooptical, electronic, electroluminescent or photoluminescent components or devices.

The invention further relates to the use of compounds and formulations according to the present invention as charge transport, semiconducting, electrically conducting, photoconducting or light emitting material in optical, electrooptical, electronic, electroluminescent or photoluminescent components or devices.

The invention further relates to a charge transport, semiconducting, electrically conducting, photoconducting or light emitting material or component comprising one or more compounds or formulations according to the present invention.

The invention further relates to an optical, electrooptical or electronic component or device comprising one or more compounds, formulations, components or materials according to the present invention.

The optical, electrooptical, electronic electroluminescent and photoluminescent components or devices include, without limitation, organic field effect transistors (OFET), thin film transistors (TFT), integrated circuits (IC), logic circuits, capacitors, radio frequency identification (RFID) tags, devices or components, organic light emitting diodes (OLED), organic light emitting transistors (OLET), flat panel displays, backlights of displays, organic photovoltaic devices (OPV), solar cells, laser diodes, photoconductors, photodetectors, electrophotographic devices, electrophotographic recording devices, organic memory devices, sensor devices, charge injection layers, charge transport layers or interlayers in polymer light emitting diodes (PLEDs), organic plasmon-emitting diodes (OPEDs), Schottky diodes, planarising layers, antistatic films, polymer electrolyte membranes (PEM), conducting substrates, conducting patterns, electrode materials in batteries, alignment layers, biosensors, biochips, security markings, security devices, and components or devices for detecting and discriminating DNA sequences.

### DETAILED DESCRIPTION OF THE INVENTION

The compounds of the present invention are easy to synthesize and exhibit several advantageous properties, like a high charge carrier mobility, a high melting point, a high solubility in organic solvents, a good processability for the device manufacture process, a high oxidative and photostability and a long lifetime in electronic devices. In addition, they show advantageous properties as discussed below.

One advantage of the compounds according to the present invention is that, compared to prior art compounds, their solubility in organic solvents can be increased without sacrificing the charge carrier mobility. Generally, to improve the solubility of a polyacene-based OSC, like ADT or pentacene, which carries solubilising substituted silylethynyl groups, it is necessary to have an increased number of carbon atoms in the substituents on the silyl groups. However, this increase in the size of the silyl groups imbalances the ratio between the length of the aromatic acene core and the diameter of the solubilising silyl groups. In prior art it has been shown that the π-stacking order of this class of materials in the crystalline state, and accordingly the charge mobility, are sensitive to this ratio (see J. E. Anthony, D. L. Eaton, S. R. Parkin, Org. Lett. 2001, 4, 15; J. E. Anthony, Chem. Rev., 2006, 106 (12), 5028). An optimised length/diameter ratio for 2-D stacking is around 2. However, this empirical rule from prior art does only apply to symmetric trialkylsilyl groups. More precisely, this ratio should be for the length of the aromatic core and the thickness of the solublising groups. By using for example alkyl groups of different sizes as in the present invention, it was now found that the thickness of the solubilising silyl groups can be fine-tuned without sacrificing the 2-D stacking of the material, which is critical for high charge carrier mobility. This can be illustrated in the X-ray crystal structures of some of the examples of the present invention. The desymmetrisation of the silyl group and the resultant molecule generally appears to boost the solubility of the materials.

One advantage of the compounds according to the present invention is that, compared to prior art compounds, their melting points can be increased for example by introducing, as solubilising substituents on the silylethynyl groups, either substituents with C—C-double bonds or aromatic rings, or two alkyl substituents with reduced size and one alkyl substituent with increased size. In the first case, it is expected that for example the alkenyl groups decrease interplanar distances in the π-stacks resulting in denser packing of the molecules, whereas in the second case, it is expected that the thickness of the solublising silyl groups is reduced. The condensed packing leads to higher lattice energy and accordingly, to an increased melting point.

The examples of the present invention demonstrate that alkenyl or aromatic substituents on the silyl groups, or unsymmetrically substituted silyl groups with two short alkyl groups such as methyl, ethyl or cyclopropyl and one longer alkyl group, show the above-mentioned advantages, as they lead to increased melting points and increased solublilty of the ADT compounds, compared for example to the symmetric trialkylsilyl substituted ADT compounds. For example, it was found that 5,11-di(tert-Butyldimethyl-silylethynyl)-2,8-difluoro-ADT has a higher melting point (above 300° C.) and a higher solubility than the symmetrically substituted 5,11-di(triethylsilylethynyl)-2,8-difluoro-ADT.

Preferably in the compounds of formula I X in each occurrence in the groups Y¹⁻⁴ has the same meaning.

Further preferred are compounds of formula I wherein X is S or Se, very preferably S.

Further preferred are compounds of formula I wherein n and m have the same meaning.

Further preferred are compounds of formula I wherein n=m=1.

The heteroacenes of the present invention are usually prepared as a mixture of isomers. Formula I thus covers isomer pairs wherein in the first isomer Y¹═Y³ and Y²═Y⁴, and in the second isomer Y¹═Y⁴ and Y²═Y³.

The compounds of the present invention include both the mixture of these isomers and the pure isomers.

Very preferred are compounds of formula I wherein the two groups ARR′R″ have the same meaning.

In the compounds of formula I, in at least one group ARR′R″, preferably in both groups ARR′R″, at least two of the substituents R, R′ and R″ are not identical. This means that in at least one group ARR′R″, preferably in both groups ARR′R″, at least one substituent R, R′ and R″ has a meaning that is different from the meanings of the other substituents R, R′ and R″.

Very preferred are compounds of formula I wherein all of R, R′ and R″ have meanings that are different from each other. Further preferred are compounds of formula I wherein two of R, R′ and R″ have the same meaning and one of R, R′ and R″ has a meaning which is different from the other two of R, R′ and R″.

Further preferred are compounds of formula I, wherein one or more of R, R′ and R″ denote or contain an alkenyl group or an aryl or heteroaryl group.

Very preferably R, R′ and R″ in the compounds of formula I are each independently selected from the group consisting of optionally substituted and straight-chain, branched or cyclic alkyl or alkoxy having 1 to 10 C atoms, which is for example methyl, ethyl, n-propyl, isopropyl, cyclopropyl, 2,3-dimethylcyclopropyl, 2,2,3,3-tetramethylcyclopropyl, cyclobutyl, cyclopentyl, methoxy or ethoxy, optionally substituted and straight-chain, branched or cyclic alkenyl, alkynyl or alkylcarbonyl having 2 to 12 C atoms, which is for example allyl, isopropenyl, 2-but-1-enyl, cis-2-but-2-enyl, 3-but-1-enyl, propynyl or acetyl, optionally substituted aryl, heteroaryl, arylalkyl or heteroarylalkyl, aryloxy or heteroaryloxy having 5 to 10 ring atoms, which is for example phenyl, p-tolyl, benzyl, 2-furanyl, 2-thienyl, 2-selenophenyl, N-methylpyrrol-2-yl or phenoxy.

R¹ and R² in formula I are preferably identical groups.

In a preferred embodiment of the present invention, R¹ and R² are selected from the group consisting of H, F, Cl, Br, I, —CN, and straight chain, branched or cyclic alkyl, alkoxy, thioalkyl, alkenyl, alkynyl, alkylcarbonyl, alkoxycarbonyl, alkylcarbonyloxy, alkylcarbonylamido, alkylamidocarbonyl or alkoxycarbonyloxy with 1 to 20, preferably 1 to 12 C atoms which is unsubstituted or substituted with one or more F or Cl atoms or OH groups or perfluorinated.

In another preferred embodiment, R¹ and/or R² in formula I denote an aromatic or heteroaromatic group with 4 to 25 ring atoms, which is mono- or polycyclic, i.e. it may also contain two or more individual rings that are connected to each other via single bonds, or contain two or more fused rings, and wherein each ring is unsubstituted or substituted with one or more groups L as defined above.

Very preferably according to this preferred embodiment R¹ and/or R² are selected from the group consisting of furan, thiophene, selenophene, N-pyrrole, pyrimidine, thiazole, thiadiazole, oxazole, oxadiazole, selenazole, and bi-, tri- or tetracyclic aryl or heteroaryl groups containing one or more of the aforementioned rings and optionally one or more benzene rings, wherein the individual rings are connected by single bonds or fused with each other, and wherein all the aforementioned groups are unsubstituted, or substituted with one or more groups L as defined above.

Preferably the aforementioned bi-, tri- or tetracyclic aryl or heteroaryl groups are selected from the group consisting of thieno[3,2-b]thiophene, dithieno[3,2-b:2′,3′-d]thiophene, selenopheno[3,2-b]selenophene-2,5-diyl, selenopheno[2,3-b]selenophene-2,5-diyl, selenopheno[3,2-b]thiophene-2,5-diyl, selenopheno[2,3-b]thiophene-2,5-diyl, benzo[1,2-b:4,5-b′]dithiophene-2,6-diyl, 2,2-dithiophene, 2,2-diselenophene, dithieno[3,2-b:2′,3′-d]silole-5,5-diyl, 4H-cyclopenta[2,1-b:3,4-b′]dithiophene-2,6-diyl, benzo[b]thiophene, benzo[b]selenophene, benzooxazole, benzothiazole, benzoselenazole, wherein all the aforementioned groups are unsubstituted, or substituted with one or more groups L as defined above.

Most preferably according to this preferred embodiment R¹ and/or R² are selected from the group consisting of the following moieties:

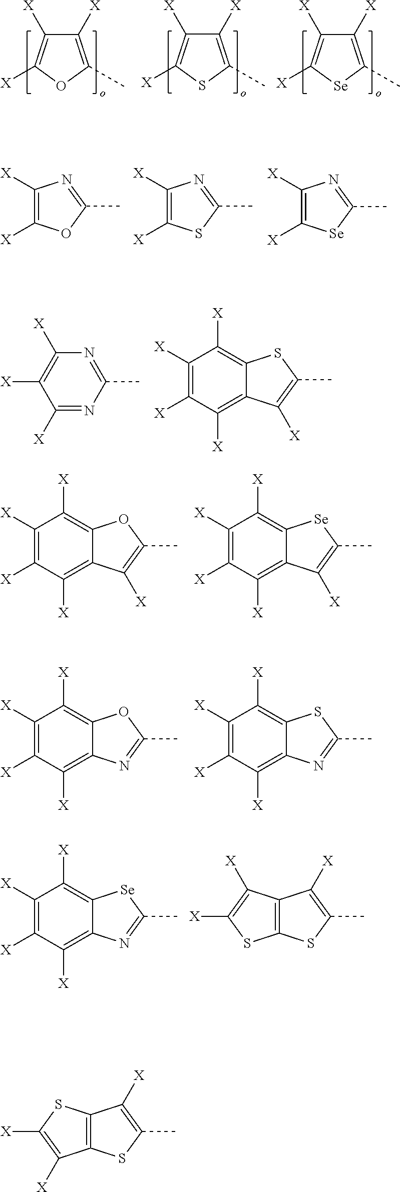

wherein X has one of the meanings of L given above, and is preferably H, F, Cl, Br, I, CN, COOH, COOR⁰, CONR⁰R⁰⁰, or alkyl or perfluoroalkyl having 1 to 20 C atoms, o is 1, 2, 3 or 4, R⁰ and R⁰⁰ are as defined above, and the dashed line denotes the linkage to the adjacent ring in formula I.

Very preferred compounds of formula I are those of the following formulae:

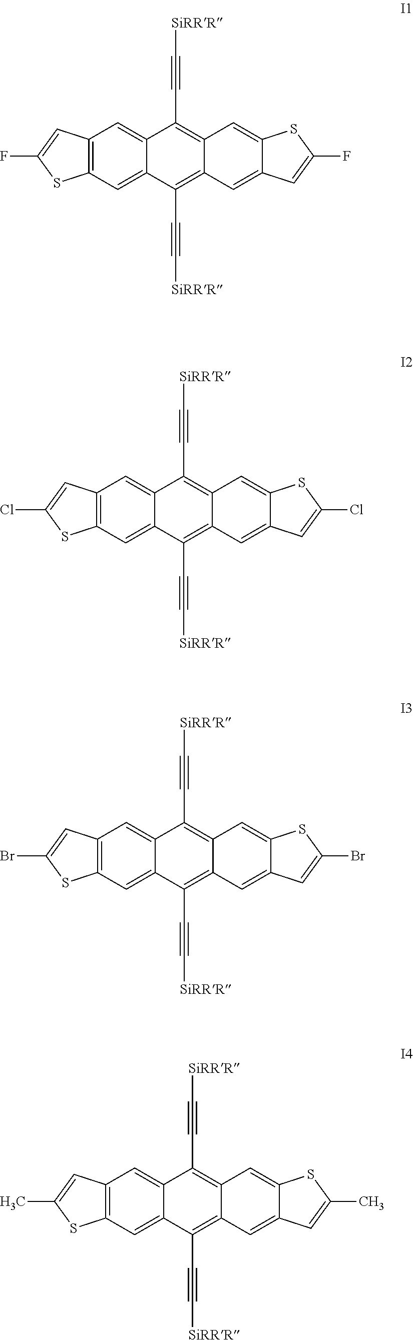

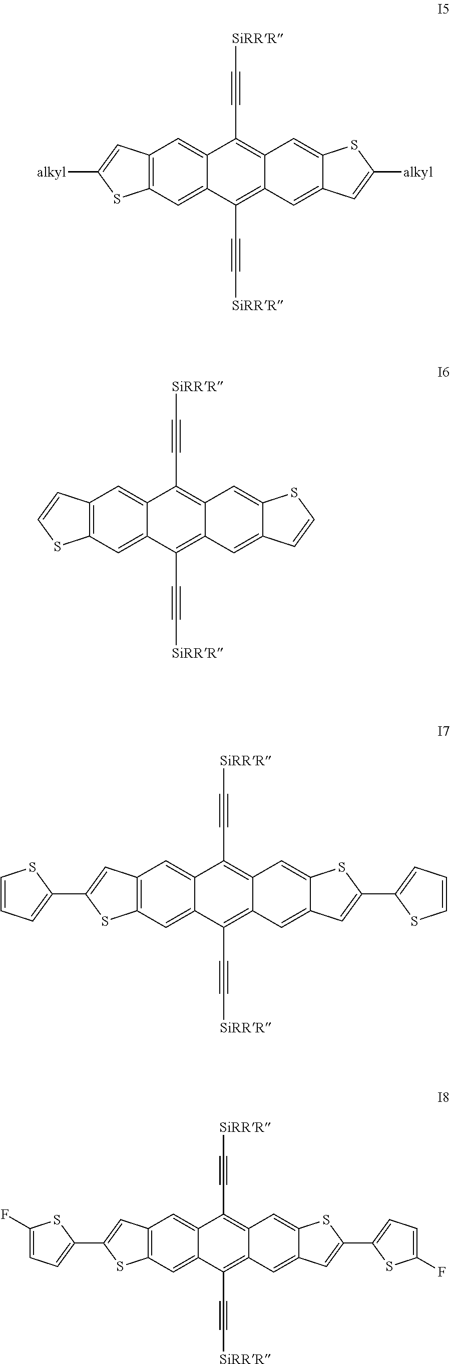

wherein R, R′ and R″ are as defined in formula I, and “alkyl” denotes alkyl with 2, 3 or 4 C atoms.

Above and below, an alkyl group or an alkoxy group, i.e. alkyl where the terminal CH₂ group is replaced by —O—, can be straight-chain or branched. It is preferably straight-chain, has 2, 3, 4, 5, 6, 7 or 8 carbon atoms and accordingly is preferably ethyl, propyl, butyl, pentyl, hexyl, heptyl, octyl, ethoxy, propoxy, butoxy, pentoxy, hexoxy, heptoxy, or octoxy, furthermore methyl, nonyl, decyl, undecyl, dodecyl, tridecyl, tetradecyl, pentadecyl, nonoxy, decoxy, undecoxy, dodecoxy, tridecoxy or tetradecoxy, for example.

An alkenyl group, i.e. alkyl wherein one or more CH₂ groups are replaced by —CH═CH— can be straight-chain or branched. It is preferably straight-chain, has 2 to 10 C atoms and accordingly is preferably vinyl, prop-1-, or prop-2-enyl, but-1-, 2- or but-3-enyl, pent-1-, 2-, 3- or pent-4-enyl, hex-1-, 2-, 3-, 4- or hex-5-enyl, hept-1-, 2-, 3-, 4-, 5- or hept-6-enyl, oct-1-, 2-, 3-, 4-, 5-, 6- or oct-7-enyl, non-1-, 2-, 3-, 4-, 5-, 6-, 7- or non-8-enyl, dec-1-, 2-, 3-, 4-, 5-, 6-, 7-, 8- or dec-9-enyl.

Especially preferred alkenyl groups are C₂₋C₇-1E-alkenyl, C₄-C₇-3E-alkenyl, C₅-C₇-4-alkenyl, C₆-C₇-5-alkenyl and C₇-6-alkenyl, in particular C₂-C₇-1E-alkenyl, C₄-C₇-3E-alkenyl and C₅-C₇-4-alkenyl. Examples for particularly preferred alkenyl groups are vinyl, 1E-propenyl, 1E-butenyl, 1E-pentenyl, 1E-hexenyl, 1E-heptenyl, 3-butenyl, 3E-pentenyl, 3E-hexenyl, 3E-heptenyl, 4-pentenyl, 4Z-hexenyl, 4E-hexenyl, 4Z-heptenyl, 5-hexenyl, 6-heptenyl and the like. Groups having up to 5 C atoms are generally preferred.

An oxaalkyl group, i.e. alkyl where a non-terminal CH₂ group is replaced by —O—, is preferably straight-chain 2-oxapropyl (=methoxymethyl), 2-(=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-,7-, 8- or 9-oxadecyl, for example.

In an alkyl group wherein one CH₂ group is replaced by —O— and another CH₂ group is replaced by —CO— , these radicals are preferably neighboured. Accordingly these radicals together form a carbonyloxy group —CO—O— or an oxycarbonyl group —O—CO—. Preferably this group is straight-chain and has 2 to 6 C atoms. It is accordingly preferably acetyloxy, propionyloxy, butyryloxy, pentanoyloxy, hexanoyloxy, acetyloxymethyl, propionyloxy-methyl, butyryloxymethyl, pentanoyloxymethyl, 2-acetyloxyethyl, 2-propionyloxyethyl, 2-butyryloxyethyl, 3-acetyloxypropyl, 3-propionyl-oxypropyl, 4-acetyloxybutyl, methoxycarbonyl, ethoxycarbonyl, propoxycarbonyl, butoxycarbonyl, pentoxycarbonyl, methoxycarbonylmethyl, ethoxycarbonylmethyl, propoxycarbonylmethyl, butoxycarbonylmethyl, 2-(methoxycarbonyl)ethyl, 2-(ethoxycarbonyl)ethyl, 2-(propoxycarbonyl)ethyl, 3-(methoxycarbonyl)propyl, 3-(ethoxycarbonyl)propyl, 4-(methoxycarbonyl)-butyl.

An alkyl group wherein two or more CH₂ groups are replaced by —O— and/or —COO— can be straight-chain or branched. It is preferably straight-chain and has 3 to 12 C atoms. Accordingly it is preferably bis-carboxy-methyl, 2,2-bis-carboxy-ethyl, 3,3-bis-carboxy-propyl, 4,4-bis-carboxy-butyl, 5,5-bis-carboxy-pentyl, 6,6-bis-carboxy-hexyl, 7,7-bis-carboxy-heptyl, 8,8-bis-carboxy-octyl, 9,9-bis-carboxy-nonyl, 10,10-bis-carboxy-decyl, bis-(methoxycarbonyl)-methyl, 2,2-bis-(methoxycarbonyl)-ethyl, 3,3-bis-(methoxycarbonyl)-propyl, 4,4-bis-(methoxycarbonyl)-butyl, 5,5-bis-(methoxycarbonyl)-pentyl, 6,6-bis-(methoxycarbonyl)-hexyl, 7,7-bis-(methoxycarbonyl)-heptyl, 8,8-bis-(methoxycarbonyl)-octyl, bis-(ethoxycarbonyl)-methyl, 2,2-bis-(ethoxycarbonyl)-ethyl, 3,3-bis-(ethoxycarbonyl)-propyl, 4,4-bis-(ethoxycarbonyl)-butyl, 5,5-bis-(ethoxycarbonyl)-hexyl.

A thioalkyl group, i.e where one CH₂ group is replaced by —S—, is preferably straight-chain thiomethyl (—SCH₃), 1-thioethyl (—SCH₂CH₃), 1-thiopropyl (═—SCH₂CH₂CH₃), 1-(thiobutyl), 1-(thiopentyl), 1-(thiohexyl), 1-(thioheptyl), 1-(thiooctyl), 1-(thiononyl), 1-(thiodecyl), 1-(thioundecyl) or 1-(thiododecyl), wherein preferably the CH₂ group adjacent to the sp² hybridised vinyl carbon atom is replaced.

R¹, R², R′, R″ and R′″ can be an achiral or a chiral group. Particularly preferred chiral groups are 2-butyl (=1-methylpropyl), 2-methylbutyl, 2-methylpentyl, 3-methylpentyl, 2-ethylhexyl, 2-propylpentyl, in particular 2-methylbutyl, 2-methylbutoxy, 2-methylpentoxy, 3-methylpentoxy, 2-ethyl-hexoxy, 1-methylhexoxy, 2-octyloxy, 2-oxa-3-methylbutyl, 3-oxa-4-methyl-pentyl, 4-methylhexyl, 2-hexyl, 2-octyl, 2-nonyl, 2-decyl, 2-dodecyl, 6-methoxyoctoxy, 6-methyloctoxy, 6-methyloctanoyloxy, 5-methylheptyl-oxycarbonyl, 2-methylbutyryloxy, 3-methylvaleroyloxy, 4-methylhexanoyloxy, 2-chlorpropionyloxy, 2-chloro-3-methylbutyryloxy, 2-chloro-4-methylvaleryloxy, 2-chloro-3-methylvaleryloxy, 2-methyl-3-oxapentyl, 2-methyl-3-oxahexyl, 1-methoxypropyl-2-oxy, 1-ethoxypropyl-2-oxy, 1-propoxypropyl-2-oxy, 1-butoxypropyl-2-oxy, 2-fluorooctyloxy, 2-fluorodecyloxy, 1,1,1-trifluoro-2-octyloxy, 1,1,1-trifluoro-2-octyl, 2-fluoromethyloctyloxy for example. Very preferred are 2-hexyl, 2-octyl, 2-octyloxy, 1,1,1-trifluoro-2-hexyl, 1,1,1-trifluoro-2-octyl and 1,1,1-trifluoro-2-octyloxy.

Preferred achiral branched groups are isopropyl, isobutyl (=methylpropyl), isopentyl (=3-methylbutyl), tertiary butyl, isopropoxy, 2-methylpropoxy and 3-methylbutoxy.

—CY⁰═CY⁰⁰— is preferably —CH═CH—, —CF═CF— or —CH═C(CN)—.

Halogen is F, Cl, Br or I, preferably F, Cl or Br.

L is preferably selected from P-Sp-, F, Cl, Br, I, —OH, —CN, —NO₂, —NCO, —NCS, —OCN, —SCN, —C(═O)NR⁰R⁰⁰, —C(═O)X⁰, —C(═O)R⁰, —NR⁰R⁰⁰, C(═O)OH, straight chain, branched or cyclic alkyl, alkoxy, oxaalkyl or thioalkyl with 1 to 20, preferably 1 to 12 C atoms which is unsubstituted or substituted with one or more F or Cl atoms or OH groups or perfluorinated, and straight chain, branched or cyclic alkenyl, alkynyl, alkylcarbonyl, alkoxycarbonyl, alkylcarbonyloxy or alkoxycarbonyloxy with 2 to 20, preferably 2 to 12 C atoms which is unsubstituted or substituted with one or more F or Cl atoms or OH groups or perfluorinated.

The compounds of formula I may also be substituted with a polymerisable or reactive group, which is optionally protected during the process of forming the polymer. Particular preferred compounds of this type are those of formula I that contain one or more substituents L which denote P-Sp, wherein P is a polymerisable or reactive group and Sp is a spacer group or a single bond. These compounds are particularly useful as semiconductors or charge transport materials, as they can be crosslinked via the groups P, for example by polymerisation in situ, during or after processing the polymer into a thin film for a semiconductor component, to yield crosslinked polymer films with high charge carrier mobility and high thermal, mechanical and chemical stability.

Preferably the polymerisable or reactive group P is selected from CH₂═CW¹—COO—, CH₂═CW¹—CO—,

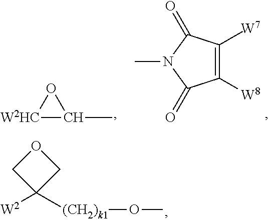

CH₂═CW²—(O)ₖ₁—, CH₃—CH═CH—O—, (CH₂═CH)₂CH—OCO—, (CH₂═CH—CH₂)₂CH—OCO—, (CH₂═CH)₂CH—O—, (CH₂═CH—CH₂)₂N—, (CH₂═CH—CH₂)₂N—CO—, HO—CW²W³—, HS—CW²W³—, HW²N—, HO—CW²W³—NH—, CH₂═CW¹—CO—NH—, CH₂═CH—(COO)ₖ₁-Phe-(O)ₖ₂—, CH₂═CH—(CO)ₖ₁-Phe-(O)ₖ₂—, Phe-CH═CH—, HOOC—, OCN—, and W⁴W⁵W⁶Si—, with W¹ being H, F, Cl, CN, CF₃, phenyl or alkyl with 1 to 5 C-atoms, in particular H, Cl or CH₃, W² and W³ being independently of each other H or alkyl with 1 to 5 C-atoms, in particular H, methyl, ethyl or n-propyl, W⁴, W⁶ and W⁶ being independently of each other Cl, oxaalkyl or oxacarbonylalkyl with 1 to 5 C-atoms, W⁷ and W⁸ being independently of each other H, Cl or alkyl with 1 to 5 C-atoms, Phe being 1,4-phenylene that is optionally substituted by one or more groups L as defined above, and k₁ and k₂ being independently of each other 0 or 1.

Alternatively P is a protected derivative of these groups which is non-reactive under the conditions described for the process according to the present invention. Suitable protective groups are known to the ordinary expert and described in the literature, for example in Green, “Protective Groups in Organic Synthesis”, John Wiley and Sons, New York (1981), like for example acetals or ketals.

Especially preferred groups P are CH₂═CH—COO—, CH₂═C(CH₃)—COO—, CH₂═CH—, CH₂═CH—O—, (CH₂═CH₂CH—OCO—, (CH₂═CH)₂CH—O—,

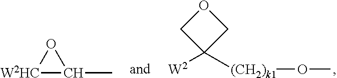

or protected derivatives thereof.

Polymerisation of group P can be carried out according to methods that are known to the ordinary expert and described in the literature, for example in D. J. Broer; G. Challa; G. N. Mol, Macromol. Chem, 1991, 192, 59.

The term “spacer group” is known in prior art and suitable spacer groups Sp are known to the ordinary expert (see e.g. Pure Appl. Chem. 73(5), 888 (2001). The spacer group Sp is preferably of formula Sp′-X′, such that P-Sp- is P-Sp′-X′—, wherein
Sp′ is alkylene with up to 30 C atoms which is unsubstituted or mono- or polysubstituted by F, Cl, Br, I or CN, it being also possible for one or more non-adjacent CH₂ groups to be replaced, in each case independently from one another, by —O—, —S—, —NH—, —NR⁰—, —SiR⁰R⁰⁰—, —CO—, —COO—, —OCO—, —OCO—O—, —S—CO—, —CO—S—, —CH═CH— or —C≡C— in such a manner that O and/or S atoms are not linked directly to one another,
X′ is —O—, —S—, —CO—, —COO—, —OCO—, —O—COO—, —CO—NR⁰—, —NR⁰—CO—, —NR⁰—CO—NR⁰⁰—, —OCH₂—, —CH₂O—, —SCH₂—, —CH₂S—, —CF₂O—, —OCF₂—, —CF₂S—, —SCF₂—, —CF₂CH₂—, —CH₂CF₂—, —CF₂CF₂—, —CH═N—, —N═CH—, —N═N—, —CH═CR⁰—, —CY⁰═CY⁰⁰—, —C≡C—, —CH═CH—COO—, —OCO—CH═CH— or a single bond,
R⁰ and R⁰⁰ are independently of each other H or alkyl with 1 to 12 C-atoms, and
Y⁰ and Y⁰⁰ are independently of each other H, F, Cl or CN.

X′ is preferably —O—, —S—, —OCH₂—, —CH₂O—, —SCH₂—, —CH₂S—, —CF₂O—, —OCF₂—, —CF₂S—, —SCF₂—, —CH₂CH₂—, —CF₂CH₂—, —CH₂CF₂—, —CF₂CF₂—, —CH═N—, —N═CH—, —N═N—, —CH═CR⁰—, —CY⁰═CY⁰⁰—, —C≡C— or a single bond, in particular —O—, —S—, —C≡C—, —CY⁰═CY⁰⁰— or a single bond. In another preferred embodiment X′ is a group that is able to form a conjugated system, such as —C≡C— or —CY⁰=CY⁰⁰—, or a single bond.

Typical groups Sp′ are, for example, —(CH₂)ₚ—, —(CH₂CH₂O)_{q}—CH₂CH₂—, —CH₂CH₂—S—CH₂CH₂— or —CH₂CH₂—NH—CH₂CH₂— or —(SiR⁰R⁰⁰—O)ₚ—, with p being an integer from 2 to 12, q being an integer from 1 to 3 and R⁰ and R⁰⁰ having the meanings given above.

Preferred groups Sp′ are ethylene, propylene, butylene, pentylene, hexylene, heptylene, octylene, nonylene, decylene, undecylene, dodecylene, octadecylene, ethyleneoxyethylene, methyleneoxybutylene, ethylene-thioethylene, ethylene-N-methyl-iminoethylene, 1-methylalkylene, ethenylene, propenylene and butenylene for example.

The compounds of formula I can be synthesized according to or in analogy to methods that are known to the skilled person and are described in the literature. Other methods of preparation can be taken from the examples. Especially preferred and suitable synthesis methods are further described below.

Suitable and preferred synthesis methods for the compounds of the present invention are exemplarily and schematically described in the reaction schemes below for anthradithiophenes of formula I wherein A-RR′R″ are e.g. allyldiisopropylsilyl, cyclohexyldimethylsilyl and tert-butyldimethylsilyl groups and R¹ and R² are e.g. F. Other derivatives with different silyl or germanyl groups or different substituents R¹ and R² can be synthesised in analogous manner.

The synthesis of the unsymmetric ADiPS-F-ADT (5,11-di-(Allyl-DiisoPropylSilylethynyl)-2,8-diFluoro-Anthra[2,3-b:7,6-b′]DiThiophene) is shown in Scheme 1. Dichlorodiisopropylsilane 1 was treated with allylmagnesium bromide solution to yield allyldiisopropylchlorosilane 2, which was then reacted with lithium (trimethylsilyl)acetylide to yield the TMS-protected ethynyl allyldiisopropylsilane 3. Deprotection of 3 with base, e.g. potassium carbonate afforded ethynyl allyldiisopropylsilane 4. Using a standard procedure, this ethynyl silane was lithiated with n-butyllithium to provide the lithium allyldiisopropylsilylacetylide 5, which is reacted with difluoro-dithienoanthraquinone 6 to yield diol 7. The diol was directly aromatized to afford the difluoro-anthra[2,3-b:7,6-b′]dithiophene 8 with SnCl₂ under acidic conditions.

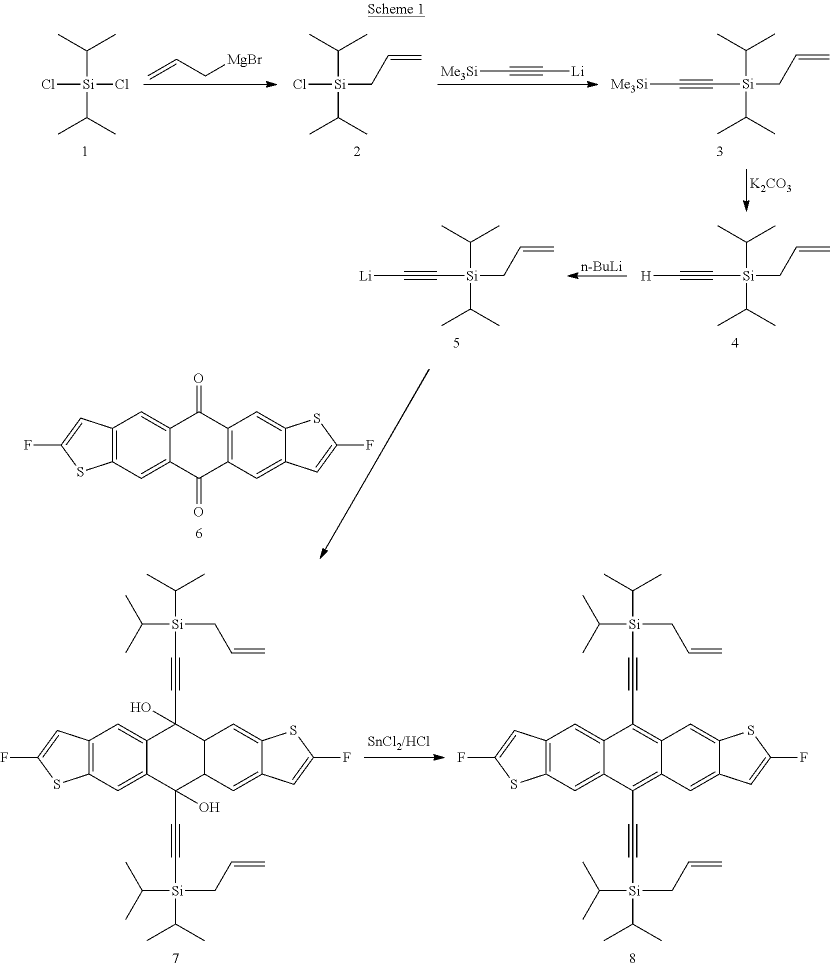

The synthesis of compounds of formula I, wherein R¹ and R² are aryl or heteroaryl groups, is exemplarily and schematically illustrated in Schemes 2 and 3 below, for compounds wherein A-RR′R″ is e.g. an allyldiisopropylsilyl group. Other derivatives with different silyl or germanyl groups or different aryl or heteroaryl substituents R¹ and R² can be synthesised in analogous manner.

Commercially available diacetal A is iodinated by treating with n-BuLi and elemental iodine to yield the iododiacetal B in good yield. The diacetal is deprotected to the corresponding the dialdehyde C, which is condensed with 1,4-cyclohexanedione to yield the diiodoanthradithiophene quinone D. The quinone reacts with the lithium allyldiisopropylsilylacetylide 5 from Scheme 1 to form the dihydroxy derivative E. Stille or Suzuki coupling of E with the corresponding thienyl building blocks yields F, which aromatises to the dithienyl anthra[2,3-b:7,6-b′]dithiophenes.

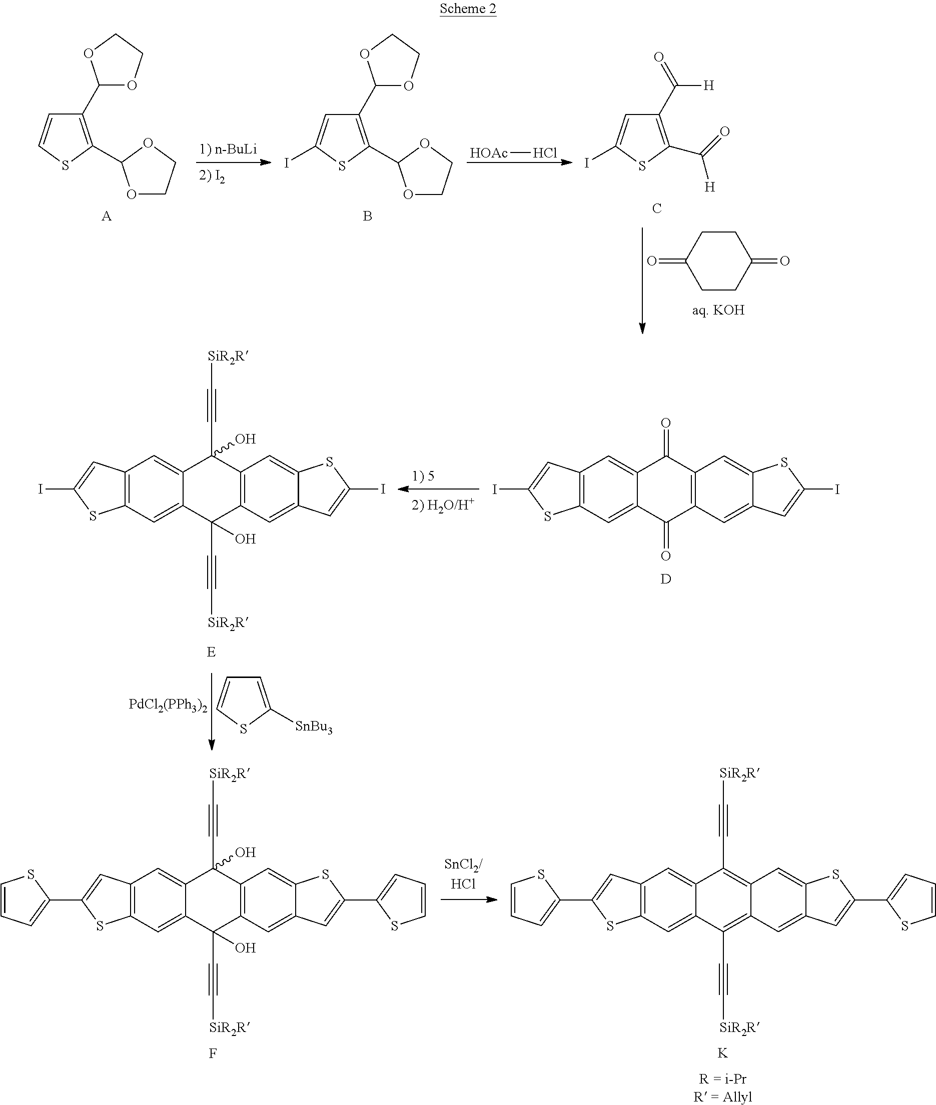

The fluorinated dithienyl anthra[2,3-b:7,6-b′]dithiophenes can be synthesised by analogous methods as shown in Scheme 3.

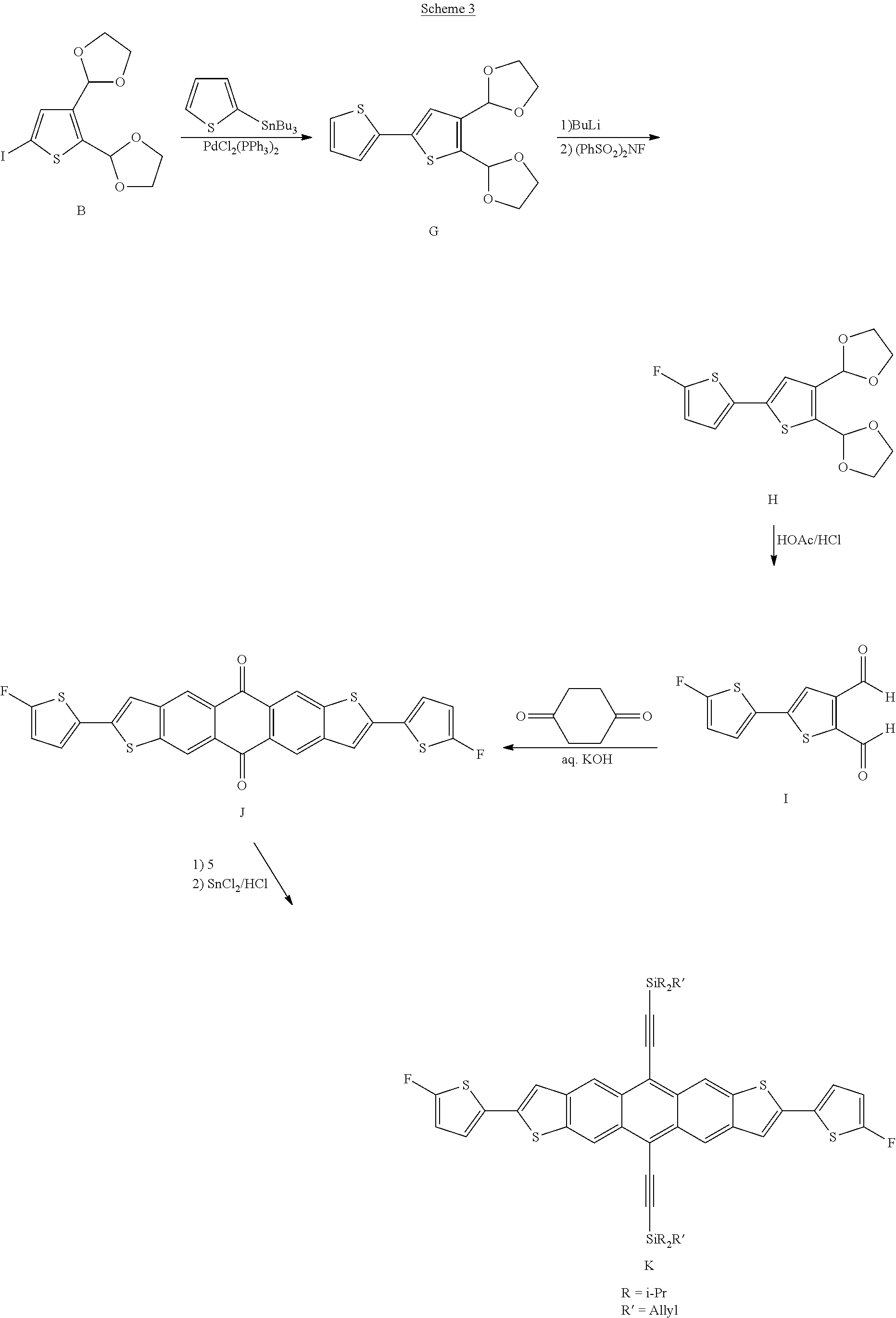

The novel methods of preparing the compounds of formula I as described above and below are another aspect of the invention. Very preferred is a general method for preparing a compound of formula I comprising the following steps:
a) Treating a dichlorosilane of the formula SiCl₂R₂ (1) with a solution of R′MgBr, wherein R and R′ are as defined in formula I, for example R is a first alkyl group and R′ is an alkenyl group or a second alkyl group that is different from the first alkyl group, to yield a chlorosilane of the formula SiClR₂R′ (2),
b) reacting the chlorosilane SiClR₂R′ (2) from step a) with Li—C≡C—SiR⁰₃, wherein R⁰ is alkyl, for example methyl, to yield the corresponding protected silane of the formula R⁰₃Si—C≡C—SiR₂R′ (3),
c) deprotecting the protected silane R⁰₃Si—C≡C—SiR₂R′ (3), for example by treatment with potassium carbonate, to afford the unprotected silane of the formula H—C≡C—SiR₂R′ (4),
b2) alternatively to steps b) and c), treating the chlorosilane SiClR₂R′ (2) from step a) with ethynylmagnesium halide or lithium acetylide to afford the unprotected silane H—C≡C—SiR₂R′ (4) directly.
d) lithiating the silane H—C≡C—SiR₂R′ (4) from step c) or b2), for example with n-butyllithium, to provide the lithium silylacetylide of the formula Li—C≡C—SiR₂R′ (5),
e) reacting the lithium silylacetylide Li—C≡C—SiR₂R′ (5) from step d) with dithienoanthraquinone (6), which is optionally substituted in 2- and/or 8-position by R¹ and/or R² as defined in formula I, to yield the corresponding diol (7),
f) reacting the diol (7) from step e) with a reducing reagent, for example SnCl₂, under acidic conditions to afford the anthra[2,3-b:7,6-b′]dithiophene (8), which is substituted by —C≡C—SiR₂R′ groups in 5- and 11-position and optionally substituted by R¹ and/or R² in 2- and/or 8-position.

Further preferred is a general method for preparing a compound of formula I comprising the following steps:
a) Reacting 2,3-Thiophenedicarboxaldehyde diacetal (A) with alkyllithium, LDA or another lithiation reagent, and then reacting the resulting compound with a halogenation agent including but not limited to carbon tetrachloride, 1,2-dichloroethane, carbon tetrabromide, 1,2-dibromotetrachloroethane, 1,2-dibromoethane, 1-iodoperfluorohexane, iodinechloride, elemental iodine, to afford the 5-halogenated 2,3-thiophenedicarboxaldehyde diacetal (B),
b) deprotecting the 5-halogenated 2,3-thiophenedicarboxaldehyde diacetal (B) from step a) under acidic conditions to the corresponding dialdehyde (C), which is then condensed with a cyclic 1,4-diketone, such as 1,4-cyclohexadione, 1,4-dihydroxy-naphthalene or its higher analogues, to yield the quinone of the dihalogenated acenodithiophene (D),
c) treating the quinone of the dihalogenated acenodithiophene (D) from step b) with a lithium silylacetylide of the formula Li—C≡C—SiR₂R′ (5), which is for example obtainable by a process as described above, and wherein R and R′ are as defined in formula I, for example R is a first alkyl group and R′ is an alkenyl group or a second alkyl group that is different from the first alkyl group, followed by a hydrolysis, for example with diluted HCl, to yield the dihalogenated diol intermediate (E),
d) cross-coupling the dihalogenated diol intermediate (E) from step c) with a corresponding heteroaryl boronic acid, boronic ester, stannane, zinc halide or magnesium halide, in the presence of a nickel or palladium complex as catalyst, to yield the heteroaryl extended diol (F),
e) reacting the heteroaryl extended diol (F) from step d) with a reducing agent, for example SnCl₂, under acidic conditions to afford the 2,8-diheteroaryl-anthra[2,3-b:7,6-b′]dithiophene (K) which is substituted by —C≡C—SiR₂R′groups in 5 and 11-position, or
b2) alternatively to steps b)-e), reacting the 5-halogenated 2,3-thiophenedicarbox-aldehyde diacetal (B) obtained by step a) in a cross-coupling reaction with a corresponding heteroaryl boronic acid, boronic ester, stannane, zinc halide or magnesium halide, in the presence of a nickel or palladium complex as catalyst, deprotecting the resulting product and condensing with a cyclic 1,4-diketone as described in step b), treating the resulting product with the lithium silylacetylide of the formula Li—C≡C—SiR₂R′ (5) followed by hydrolysis as described in step c), and aromatising the resulting 2,8-diheteroaryl extended diol by reacting it with a reducing agent as described in step e), to afford the 2,8-diheteroaryl-anthra[2,3-b:7,6-b′]dithiophene (K) which is substituted by —C≡C—SiR₂R′groups in 5 and 11-position.

The invention further relates to a formulation comprising one or more compounds of formula I and one or more solvents, preferably selected from organic solvents.

Preferred solvents are aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetramethyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, dimethylformamide, 2-chloro-6fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylansiole, 3-methylanisole, 4-fluoro-3-methylanisole, 2-fluorobenzonitrile, 4-fluoroveratrol, 2,6-dimethylanisole, 3-fluorobenzonitrile, 2,5-dimethylanisole, 2,4-dimethylanisole, benzonitrile, 3,5-dimethylanisole, N,N-dimethylaniline, ethyl benzoate, 1-fluoro-3,5-dimethoxybenzene, 1-methylnaphthalene, N-methylpyrrolidinone, 3-fluorobenzotrifluoride, benzotrifluoride, benzotrifluoride, diosane, trifluoromethoxybenzene, 4-fluorobenzotrifluoride, 3-fluoropyridine, toluene, 2-fluorotoluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluorobenzene, 3-chlorofluorobenzene, 1-chloro-2,5-difluorobenzene, 4-chlorofluorobenzene, chlorobenzene, o-dichlorobenzene, 2-chlorofluorobenzene, p-xylene, m-xylene, o-xylene or mixture of o-, m-, and p-isomers. Solvents with relatively low polarity are generally preferred. For inkjet printing solvents with high boiling temperatures and solvent mixtures are preferred. For spin coating alkylated benzenes like xylene and toluene are preferred.

The invention further relates to an organic semiconducting formulation comprising one or more compounds of formula I, one or more organic binders, or precursors thereof, preferably having a permittivity ε at 1,000 Hz of 3.3 or less, and optionally one or more solvents.

Combining specified soluble compounds of formula I, especially compounds of the preferred formulae as described above and below, with an organic binder resin (hereinafter also referred to as “the binder”) results in little or no reduction in charge mobility of the compounds of formula I, even an increase in some instances. For instance, the compounds of formula I may be dissolved in a binder resin (for example poly(α-methylstyrene) and deposited (for example by spin coating), to form an organic semiconducting layer yielding a high charge mobility. Moreover, a semiconducting layer formed thereby exhibits excellent film forming characteristics and is particularly stable.

If an organic semiconducting layer formulation of high mobility is obtained by combining a compound of formula I with a binder, the resulting formulation leads to several advantages. For example, since the compounds of formula I are soluble they may be deposited in a liquid form, for example from solution. With the additional use of the binder the formulation can be coated onto a large area in a highly uniform manner. Furthermore, when a binder is used in the formulation it is possible to control the properties of the formulation to adjust to printing processes, for example viscosity, solid content, surface tension. Whilst not wishing to be bound by any particular theory it is also anticipated that the use of a binder in the formulation fills in volume between crystalline grains otherwise being void, making the organic semiconducting layer less sensitive to air and moisture. For example, layers formed according to the process of the present invention show very good stability in OFET devices in air.

The invention also provides an organic semiconducting layer which comprises the organic semiconducting layer formulation.

The invention further provides a process for preparing an organic semiconducting layer, said process comprising the following steps:
(i) depositing on a substrate a liquid layer of a formulation comprising one or more compounds of formula I as described above and below, one or more organic binder resins or precursors thereof, and optionally one or more solvents,
(ii) forming from the liquid layer a solid layer which is the organic semiconducting layer,
(iii) optionally removing the layer from the substrate.

The process is described in more detail below.

The invention additionally provides an electronic device comprising the said organic semiconducting layer. The electronic device may include, without limitation, an organic field effect transistor (OFET), organic light emitting diode (OLED), photodetector, sensor, logic circuit, memory element, capacitor or photovoltaic (PV) cell. For example, the active semiconductor channel between the drain and source in an OFET may comprise the layer of the invention. As another example, a charge (hole or electron) injection or transport layer in an OLED device may comprise the layer of the invention. The formulations according to the present invention and layers formed therefrom have particular utility in OFETs especially in relation to the preferred embodiments described herein.

The semiconducting compound of formula I preferably has a charge carrier mobility, μ, of more than 0.001 cm²V⁻¹s⁻¹, very preferably of more than 0.01 cm²V⁻¹s⁻¹, especially preferably of more than 0.1 cm²V⁻¹s⁻¹ and most preferably of more than 0.5 cm²V⁻¹s⁻¹.

The binder, which is typically a polymer, may comprise either an insulating binder or a semiconducting binder, or mixtures thereof may be referred to herein as the organic binder, the polymeric binder or simply the binder.

Preferred binders according to the present invention are materials of low permittivity, that is, those having a permittivity ε at 1,000 Hz of 3.3 or less. The organic binder preferably has a permittivity ε at 1,000 Hz of 3.0 or less, more preferably 2.9 or less. Preferably the organic binder has a permittivity ε at 1,000 Hz of 1.7 or more. It is especially preferred that the permittivity of the binder is in the range from 2.0 to 2.9. Whilst not wishing to be bound by any particular theory it is believed that the use of binders with a permittivity ε of greater than 3.3 at 1,000 Hz, may lead to a reduction in the OSC layer mobility in an electronic device, for example an OFET. In addition, high permittivity binders could also result in increased current hysteresis of the device, which is undesirable.

An example of a suitable organic binder is polystyrene. Further examples of suitable binders are disclosed for example in US 2007/0102696 A1. Especially suitable and preferred binders are described in the following.

In one type of preferred embodiment, the organic binder is one in which at least 95%, more preferably at least 98% and especially all of the atoms consist of hydrogen, fluorine and carbon atoms.

It is preferred that the binder normally contains conjugated bonds, especially conjugated double bonds and/or aromatic rings.

The binder should preferably be capable of forming a film, more preferably a flexible film. Polymers of styrene and a-methyl styrene, for example copolymers including styrene, α-methylstyrene and butadiene may suitably be used.

Binders of low permittivity of use in the present invention have few permanent dipoles which could otherwise lead to random fluctuations in molecular site energies. The permittivity ε (dielectric constant) can be determined by the ASTM D150 test method.

It is also preferred that in the present invention binders are used which have solubility parameters with low polar and hydrogen bonding contributions as materials of this type have low permanent dipoles. A preferred range for the solubility parameters (‘Hansen parameter’) of a binder for use in accordance with the present invention is provided in Table 1 below.

TABLE 1

| | Hansen parameter | | |
|---|---|---|---|
| | δ_{d} MPa^{1/2} | δₚ MPa^{1/2} | δₕ MPa^{1/2} |
| Preferred range | 14.5+ | 0-10 | 0-14 |
| More preferred range | 16+ | 0-9 | 0-12 |
| Most preferred range | 17+ | 0-8 | 0-10 |

The three dimensional solubility parameters listed above include: dispersive (δ_{d}), polar (δₚ) and hydrogen bonding (δₕ) components (C. M. Hansen, Ind. Eng. and Chem., Prod. Res. and Devl., 9, No 3, p 282., 1970). These parameters may be determined empirically or calculated from known molar group contributions as described in Handbook of Solubility Parameters and Other Cohesion Parameters ed. A.F.M. Barton, CRC Press, 1991. The solubility parameters of many known polymers are also listed in this publication.

It is desirable that the permittivity of the binder has little dependence on frequency. This is typical of non-polar materials. Polymers and/or copolymers can be chosen as the binder by the permittivity of their substituent groups. A list of suitable and preferred low polarity binders is given (without limiting to these examples) in Table 2:

TABLE 2

| | typical low frequency |
|---|---|
| Binder | permittivity (ε) |
| polystyrene | 2.5 |
| poly(α-methylstyrene) | 2.6 |
| poly(α-vinylnaphtalene) | 2.6 |
| poly(vinyltoluene) | 2.6 |
| polyethylene | 2.2-2.3 |
| cis-polybutadiene | 2.0 |
| polypropylene | 2.2 |
| polyisoprene | 2.3 |
| poly(4-methyl-1-pentene) | 2.1 |
| poly (4-methylstyrene) | 2.7 |
| poly(chorotrifluoroethylene) | 2.3-2.8 |
| poly(2-methyl-1,3-butadiene) | 2.4 |
| poly(p-xylylene) | 2.6 |
| poly(α-α-α′-α′ tetrafluoro-p-xylylene) | 2.4 |
| poly[1,1-(2-methyl propane)bis(4- | 2.3 |
| phenyl)carbonate] | |
| poly(cyclohexyl methacrylate) | 2.5 |
| poly(chlorostyrene) | 2.6 |
| poly(2,6-dimethyl-1,4-phenylene ether) | 2.6 |
| polyisobutylene | 2.2 |
| poly(vinyl cyclohexane) | 2.2 |
| poly(vinylcinnamate) | 2.9 |
| poly(4-vinylbiphenyl) | 2.7 |

Further preferred binders are poly(1,3-butadiene) and polyphenylene.

Especially preferred are formulations wherein the binder is selected from poly-α-methyl styrene, polystyrene and polytriarylamine or any copolymers of these, and the solvent is selected from xylene(s), toluene, tetralin and cyclohexanone.

Copolymers containing the repeat units of the above polymers are also suitable as binders. Copolymers offer the possibility of improving compatibility with the compounds of formula I, modifying the morphology and/or the glass transition temperature of the final layer composition. It will be appreciated that in the above table certain materials are insoluble in commonly used solvents for preparing the layer. In these cases analogues can be used as copolymers. Some examples of copolymers are given in Table 3 (without limiting to these examples). Both random or block copolymers can be used. It is also possible to add more polar monomer components as long as the overall composition remains low in polarity.

TABLE 3

| | typical low frequency |
|---|---|
| Binder | permittivity (ε) |
| poly(ethylene/tetrafluoroethylene) | 2.6 |
| poly(ethylene/chlorotrifluoroethylene) | 2.3 |
| fluorinated ethylene/propylene copolymer | 2-2.5 |
| polystyrene-co-α-methylstyrene | 2.5-2.6 |
| ethylene/ethyl acrylate copolymer | 2.8 |
| poly(styrene/10% butadiene) | 2.6 |
| poly(styrene/15% butadiene) | 2.6 |
| poly(styrene/2,4 dimethylstyrene) | 2.5 |
| Topas ™ (all grades) | 2.2-2.3 |

Other copolymers may include: branched or non-branched polystyrene-block-polybutadiene, polystyrene-block(polyethylene-ran-butylene)-block-polystyrene, polystyrene-block-polybutadiene-block-polystyrene, polystyrene-(ethylene-propylene)-diblock-copolymers (e.g. KRATON®-G1701E, Shell), poly(propylene-co-ethylene) and poly(styrene-co-methylmethacrylate).

Preferred insulating binders for use in the organic semiconductor layer formulation according to the present invention are poly(α-methylstyrene), polyvinylcinnamate, poly(4-vinylbiphenyl), poly(4-methylstyrene), and Topas™ 8007 (linear olefin, cyclo-olefin(norbornene) copolymer available from Ticona, Germany). Most preferred insulating binders are poly(α-methylstyrene), polyvinylcinnamate and poly(4-vinylbiphenyl).

The binder can also be selected from crosslinkable binders, like e.g. acrylates, epoxies, vinylethers, thiolenes etc., preferably having a sufficiently low permittivity, very preferably of 3.3 or less. The binder can also be mesogenic or liquid crystalline.

As mentioned above the organic binder may itself be a semiconductor, in which case it will be referred to herein as a semiconducting binder. The semiconducting binder is still preferably a binder of low permittivity as herein defined. Semiconducting binders for use in the present invention preferably have a number average molecular weight (Mₙ) of at least 1500-2000, more preferably at least 3000, even more preferably at least 4000 and most preferably at least 5000. The semiconducting binder preferably has a charge carrier mobility, μ, of at least 10⁻⁵ cm²V⁻¹s⁻¹, more preferably at least 10⁻⁴ cm²V⁻¹s⁻¹.

A preferred class of semiconducting binder is a polymer as disclosed in U.S. Pat. No. 6,630,566, preferably an oligomer or polymer having repeat units of formula 1:

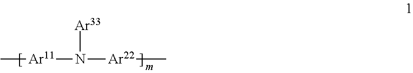

wherein
Ar¹¹, Ar²² and Ar³³ which may be the same or different, denote, independently if in different repeat units, an optionally substituted aromatic group that is mononuclear or polynuclear, and
m is an integer ≧1, preferably ≧6, preferably ≧10, more preferably ≧15 and most preferably ≧20.

In the context of Ar¹¹, Ar²² and Ar³³, a mononuclear aromatic group has only one aromatic ring, for example phenyl or phenylene. A polynuclear aromatic group has two or more aromatic rings which may be fused (for example napthyl or naphthylene), individually covalently linked (for example biphenyl) and/or a combination of both fused and individually linked aromatic rings. Preferably each Ar¹¹, Ar²² and Ar³³ is an aromatic group which is substantially conjugated over substantially the whole group.

Further preferred classes of semiconducting binders are those containing substantially conjugated repeat units. The semiconducting binder polymer may be a homopolymer or copolymer (including a block-copolymer) of the general formula 2:

A_{(c)}B_{(d)} . . . Z_{(z)} 2

wherein A, B, . . . , Z each represent a monomer unit and (c), (d), . . . (z) each represent the mole fraction of the respective monomer unit in the polymer, that is each (c), (d), . . . (z) is a value from 0 to 1 and the total of (c)+(d)+ . . . +(z)=1.

Examples of suitable and preferred monomer units A, B, . . . Z include units of formula 1 above and of formulae 3 to 8 given below (wherein m is as defined in formula 1:

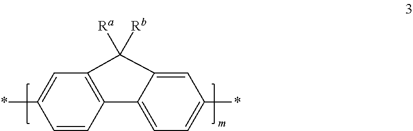

wherein
R^{a} and R^{b} are independently of each other selected from H, F, CN, NO₂, —N(R^{c})(R^{d}) or optionally substituted alkyl, alkoxy, thioalkyl, acyl, aryl,
R^{c} and R^{d} are independently or each other selected from H, optionally substituted alkyl, aryl, alkoxy or polyalkoxy or other substituents,

and wherein the asterisk (*) is any terminal or end capping group including H, and the alkyl and aryl groups are optionally fluorinated;

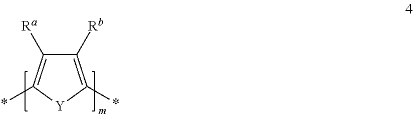

wherein
Y is Se, Te, O, S or —N(R^{e}), preferably O, S or —N(R^{e})—,
R^{e} is H, optionally substituted alkyl or aryl,
R^{a} and R^{b} are as defined in formula 3;

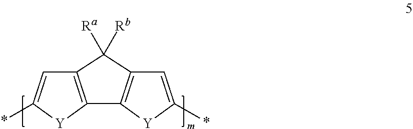

wherein R^{a}, R^{b} and Y are as defined in formulae 3 and 4;

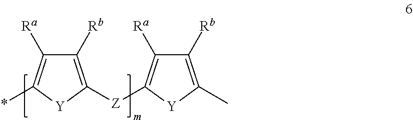

wherein R^{a}, R^{b} and Y are as defined in formulae 3 and 4,
Z is —C(T¹)=C(T²)-, —C≡C—, —N(R^{f})—, —N═N—, (R^{f})═N—, —N═C(R^{f})—,
T^{1 and T}² independently of each other denote H, Cl, F, —CN or lower alkyl with 1 to 8 C atoms,
R^{f} is H or optionally substituted alkyl or aryl;

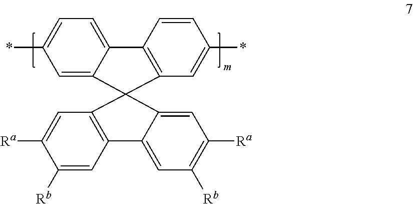

wherein R^{a} and R^{b} are as defined in formula 3;

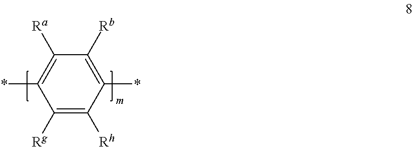

wherein R^{a}, R^{b}, R^{g} and R^{h} independently of each other have one of the meanings of R^{a} and R^{b} in formula 3.

In the case of the polymeric formulae described herein, such as formulae 1 to 8, the polymers may be terminated by any terminal group, that is any end-capping or leaving group, including H.

In the case of a block-copolymer, each monomer A, B, . . . Z may be a conjugated oligomer or polymer comprising a number, for example 2 to 50, of the units of formulae 3-8. The semiconducting binder preferably includes: arylamine, fluorene, thiophene, spiro bifluorene and/or optionally substituted aryl (for example phenylene) groups, more preferably arylamine, most preferably triarylamine groups. The aforementioned groups may be linked by further conjugating groups, for example vinylene.

In addition, it is preferred that the semiconducting binder comprises a polymer (either a homo-polymer or copolymer, including block-copolymer) containing one or more of the aforementioned arylamine, fluorene, thiophene and/or optionally substituted aryl groups. A preferred semiconducting binder comprises a homo-polymer or copolymer (including block-copolymer) containing arylamine (preferably triarylamine) and/or fluorene units. Another preferred semiconducting binder comprises a homo-polymer or co-polymer (including block-copolymer) containing fluorene and/or thiophene units.

The semiconducting binder may also contain carbazole or stilbene repeat units. For example, polyvinylcarbazole, polystilbene or their copolymers may be used. The semiconducting binder may optionally contain DBBDT segments (for example repeat units as described for formula 1 above) to improve compatibility with the soluble compounds of formula.

Very preferred semiconducting binders for use in the organic semiconductor formulation according to the present invention are poly(9-vinylcarbazole) and PTAA1, a polytriarylamine of the following formula

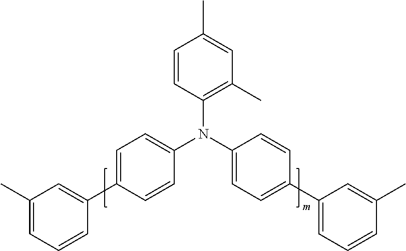

wherein m is as defined in formula 1.

For application of the semiconducting layer in p-channel FETs, it is desirable that the semiconducting binder should have a higher ionisation potential than the semiconducting compound of formula I, otherwise the binder may form hole traps. In n-channel materials the semiconducting binder should have lower electron affinity than the n-type semiconductor to avoid electron trapping.

The formulation according to the present invention may be prepared by a process which comprises:
(i) first mixing a compound of formula I and an organic binder or a precursor thereof. Preferably the mixing comprises mixing the two components together in a solvent or solvent mixture,
(ii) applying the solvent(s) containing the compound of formula I and the organic binder to a substrate; and optionally evaporating the solvent(s) to form a solid organic semiconducting layer according to the present invention,
(iii) and optionally removing the solid layer from the substrate or the substrate from the solid layer.

In step (i) the solvent may be a single solvent or the compound of formula I and the organic binder may each be dissolved in a separate solvent followed by mixing the two resultant solutions to mix the compounds.

The binder may be formed in situ by mixing or dissolving a compound of formula I in a precursor of a binder, for example a liquid monomer, oligomer or crosslinkable polymer, optionally in the presence of a solvent, and depositing the mixture or solution, for example by dipping, spraying, painting or printing it, on a substrate to form a liquid layer and then curing the liquid monomer, oligomer or crosslinkable polymer, for example by exposure to radiation, heat or electron beams, to produce a solid layer. If a preformed binder is used it may be dissolved together with the compound of formula I in a suitable solvent, and the solution deposited for example by dipping, spraying, painting or printing it on a substrate to form a liquid layer and then removing the solvent to leave a solid layer. It will be appreciated that solvents are chosen which are able to dissolve both the binder and the compound of formula I, and which upon evaporation from the solution blend give a coherent defect free layer.

Suitable solvents for the binder or the compound of formula I can be determined by preparing a contour diagram for the material as described in ASTM Method D 3132 at the concentration at which the mixture will be employed. The material is added to a wide variety of solvents as described in the ASTM method.

It will also be appreciated that in accordance with the present invention the formulation may also comprise two or more compounds of formula I and/or two or more binders or binder precursors, and that the process for preparing the formulation may be applied to such formulations.

Examples of suitable and preferred organic solvents include, without limitation, dichloromethane, trichloromethane, monochlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, dimethylformamide, dimethylacetamide, dimethylsulfoxide, tetralin, decalin, indane and/or mixtures thereof.

After the appropriate mixing and ageing, solutions are evaluated as one of the following categories: complete solution, borderline solution or insoluble. The contour line is drawn to outline the solubility parameter-hydrogen bonding limits dividing solubility and insolubility. ‘Complete’ solvents falling within the solubility area can be chosen from literature values such as published in “Crowley, J. D., Teague, G. S. Jr and Lowe, J. W. Jr., Journal of Paint Technology, 38, No 496, 296 (1966)”. Solvent blends may also be used and can be identified as described in “Solvents, W. H. Ellis, Federation of Societies for Coatings Technology, p 9-10, 1986”. Such a procedure may lead to a blend of ‘non’ solvents that will dissolve both the binder and the compound of formula I, although it is desirable to have at least one true solvent in a blend.

Especially preferred solvents for use in the formulation according to the present invention, with insulating or semiconducting binders and mixtures thereof, are xylene(s), toluene, tetralin and o-dichlorobenzene.

The proportions of binder to the compound of formula I in the formulation or layer according to the present invention are typically 20:1 to 1:20 by weight, preferably 10:1 to 1:10 more preferably 5:1 to 1:5, still more preferably 3:1 to 1:3 further preferably 2:1 to 1:2 and especially 1:1. Surprisingly and beneficially, dilution of the compound of formula I in the binder has been found to have little or no detrimental effect on the charge mobility, in contrast to what would have been expected from the prior art.

In accordance with the present invention it has further been found that the level of the solids content in the organic semiconducting layer formulation is also a factor in achieving improved mobility values for electronic devices such as OFETs. The solids content of the formulation is commonly expressed as follows:

$$Solids content ( \% ) = \frac{a + b}{a + b + c} \times 100$$

wherein a=mass of compound of formula I, b=mass of binder and c=mass of solvent.

The solids content of the formulation is preferably 0.1 to 10% by weight, more preferably 0.5 to 5% by weight.

Surprisingly and beneficially, dilution of the compound of formula I in the binder has been found to have little or no effect on the charge mobility, in contrast to what would have been expected from the prior art.

The compounds according to the present invention can also be used in mixtures or blends, for example together with other compounds having charge-transport, semiconducting, electrically conducting, photoconducting and/or light emitting semiconducting properties. Thus, another aspect of the invention relates to a mixture or blend comprising one or more compounds of formula I and one or more further compounds having one or more of the above-mentioned properties. These mixtures can be prepared by conventional methods that are described in prior art and known to the skilled person. Typically the compounds are mixed with each other or dissolved in suitable solvents and the solutions combined.

The formulations according to the present invention can additionally comprise one or more further components like for example surface-active compounds, lubricating agents, wetting agents, dispersing agents, hydrophobing agents, adhesive agents, flow improvers, defoaming agents, deaerators, diluents which may be reactive or non-reactive, auxiliaries, colourants, dyes or pigments, sensitizers, stabilizers, nanoparticles or inhibitors.

It is desirable to generate small structures in modern microelectronics to reduce cost (more devices/unit area), and power consumption. Patterning of the layer of the invention may be carried out by photolithography or electron beam lithography.

Liquid coating of organic electronic devices such as field effect transistors is more desirable than vacuum deposition techniques. The formulations of the present invention enable the use of a number of liquid coating techniques. The organic semiconductor layer may be incorporated into the final device structure by, for example and without limitation, dip coating, spin coating, ink jet printing, letter-press printing, screen printing, doctor blade coating, roller printing, reverse-roller printing, offset lithography printing, flexographic printing, web printing, spray coating, brush coating or pad printing. The present invention is particularly suitable for use in spin coating the organic semiconductor layer into the final device structure.

Selected formulations of the present invention may be applied to prefabricated device substrates by ink jet printing or microdispensing. Preferably industrial piezoelectric print heads such as but not limited to those supplied by Aprion, Hitachi-Koki, InkJet Technology, On Target Technology, Picojet, Spectra, Trident, Xaar may be used to apply the organic semiconductor layer to a substrate. Additionally semi-industrial heads such as those manufactured by Brother, Epson, Konica, Seiko Instruments Toshiba TEC or single nozzle microdispensers such as those produced by Microdrop and Microfab may be used.

In order to be applied by ink jet printing or microdispensing, the mixture of the compound of formula I and the binder should be first dissolved in a suitable solvent. Solvents must fulfil the requirements stated above and must not have any detrimental effect on the chosen print head.

Additionally, solvents should have boiling points >100° C., preferably >140° C. and more preferably >150° C. in order to prevent operability problems caused by the solution drying out inside the print head. Suitable solvents include substituted and non-substituted xylene derivatives, di-C₁₋₂-alkyl formamide, substituted and non-substituted anisoles and other phenol-ether derivatives, substituted heterocycles such as substituted pyridines, pyrazines, pyrimidines, pyrrolidinones, substituted and non-substituted N,N-di-C₁₋₂-alkylanilines and other fluorinated or chlorinated aromatics.

A preferred solvent for depositing a formulation according to the present invention by ink jet printing comprises a benzene derivative which has a benzene ring substituted by one or more substituents wherein the total number of carbon atoms among the one or more substituents is at least three. For example, the benzene derivative may be substituted with a propyl group or three methyl groups, in either case there being at least three carbon atoms in total. Such a solvent enables an ink jet fluid to be formed comprising the solvent with the binder and the compound of formula I which reduces or prevents clogging of the jets and separation of the components during spraying. The solvent(s) may include those selected from the following list of examples: dodecylbenzene, 1-methyl-4-tert-butylbenzene, terpineol limonene, isodurene, terpinolene, cymene, diethylbenzene. The solvent may be a solvent mixture, that is a combination of two or more solvents, each solvent preferably having a boiling point >100° C., more preferably >140° C. Such solvent(s) also enhance film formation in the layer deposited and reduce defects in the layer.

The ink jet fluid (that is mixture of solvent, binder and semiconducting compound) preferably has a viscosity at 20° C. of 1 to 100 mPa·s, more preferably 1 to 50 mPa·s and most preferably 1 to 30 mPa·s.

The use of the binder in the present invention allows tuning the viscosity of the coating solution, to meet the requirements of particular print heads.

The semiconducting layer of the present invention is typically at most 1 micron (=1 μm) thick, although it may be thicker if required. The exact thickness of the layer will depend, for example, upon the requirements of the electronic device in which the layer is used. For use in an OFET or OLED, the layer thickness may typically be 500 nm or less.

In the semiconducting layer of the present invention there may be used two or more different compounds of formula I. Additionally or alternatively, in the semiconducting layer there may be used two or more organic binders of the present invention.

As mentioned above, the invention further provides a process for preparing the organic semiconducting layer which comprises (i) depositing on a substrate a liquid layer of a formulation which comprises one or more compounds of formula I, one or more organic binders or precursors thereof and optionally one or more solvents, and (ii) forming from the liquid layer a solid layer which is the organic semiconducting layer.

In the process, the solid layer may be formed by evaporation of the solvent and/or by reacting the binder resin precursor (if present) to form the binder resin in situ. The substrate may include any underlying device layer, electrode or separate substrate such as silicon wafer or polymer substrate for example.

In a particular embodiment of the present invention, the binder may be alignable, for example capable of forming a liquid crystalline phase. In that case the binder may assist alignment of the compound of formula I, for example such that their aromatic core is preferentially aligned along the direction of charge transport. Suitable processes for aligning the binder include those processes used to align polymeric organic semiconductors and are described in prior art, for example in US 2004/0248338 A1.

The formulation according to the present invention can additionally comprise one or more further components like for example surface-active compounds, lubricating agents, wetting agents, dispersing agents, hydrophobing agents, adhesive agents, flow improvers, defoaming agents, deaerators, diluents, reactive or non-reactive diluents, auxiliaries, colourants, dyes or pigments, furthermore, especially in case crosslinkable binders are used, catalysts, sensitizers, stabilizers, inhibitors, chain-transfer agents or co-reacting monomers.

The present invention also provides the use of the semiconducting compound, formulation or layer in an electronic device. The formulation may be used as a high mobility semiconducting material in various devices and apparatus. The formulation may be used, for example, in the form of a semiconducting layer or film. Accordingly, in another aspect, the present invention provides a semiconducting layer for use in an electronic device, the layer comprising the formulation according to the invention. The layer or film may be less than about 30 microns. For various electronic device applications, the thickness may be less than about 1 micron thick. The layer may be deposited, for example on a part of an electronic device, by any of the aforementioned solution coating or printing techniques.

The compounds and formulations according to the present invention are useful as charge transport, semiconducting, electrically conducting, photoconducting or light mitting materials in optical, electrooptical, electronic, electroluminescent or photoluminescent components or devices. Especially preferred devices are OFETs, TFTs, ICs, logic circuits, capacitors, RFID tags, OLEDs, OLETs, OPEDs, OPVs, solar cells, laser diodes, photoconductors, photodetectors, electrophotographic devices, electrophotographic recording devices, organic memory devices, sensor devices, charge injection layers, Schottky diodes, planarising layers, antistatic films, conducting substrates and conducting patterns. In these devices, the compounds of the present invention are typically applied as thin layers or films.

For example, the compound or formulation may be used as a layer or film, in a field effect transistor (FET) for example as the semiconducting channel, organic light emitting diode (OLED) for example as a hole or electron injection or transport layer or electroluminescent layer, photodetector, chemical detector, photovoltaic cell (PVs), capacitor sensor, logic circuit, display, memory device and the like. The compound or formulation may also be used in electrophotographic (EP) apparatus.

The compound or formulation is preferably solution coated to form a layer or film in the aforementioned devices or apparatus to provide advantages in cost and versatility of manufacture. The improved charge carrier mobility of the compound or formulation of the present invention enables such devices or apparatus to operate faster and/or more efficiently.

Especially preferred electronic device are OFETs, OLEDs and OPV devices, in particular bulk heterojunction (BHJ) OPV devices. In an OFET, for example, the active semiconductor channel between the drain and source may comprise the layer of the invention. As another example, in an OLED device, the charge (hole or electron) injection or transport layer may comprise the layer of the invention.

For use in OPV devices the polymer according to the present invention is preferably used in a formulation that comprises or contains, more preferably consists essentially of, very preferably exclusively of, a p-type (electron donor) semiconductor and an n-type (electron acceptor) semiconductor. The p-type semiconductor is constituted by a compound according to the present invention. The n-type semiconductor can be an inorganic material such as zinc oxide or cadmium selenide, or an organic material such as a fullerene derivate, for example (6,6)-phenyl-butyric acid methyl ester derivatized methano C₆₀ fullerene, also known as “PCBM” or “C₆₀PCBM”, as disclosed for example in G. Yu, J. Gao, J. C. Hummelen, F. Wudl, A. J. Heeger, Science, 1995, 270, 1789 and having the structure shown below, or an structural analogous compound with e.g. a C₇₀ fullerene group (C₇₀PCBM), or a polymer (see for example Coakley, K. M. and McGehee, M. D. Chem. Mater., 2004, 16, 4533).

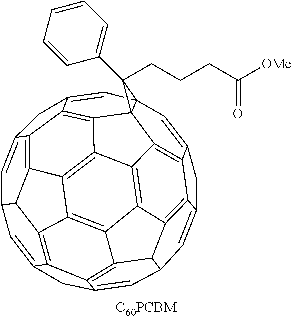

A preferred material of this type is a blend or mixture of an acene compound according to the present invention with a C₆₀ or C₇₀ fullerene or modified fullerene like PCBM. Preferably the ratio acene:fullerene is from 2:1 to 1:2 by weight, more preferably from 1.2:1 to 1:1.2 by weight, most preferably 1:1 by weight. For the blended mixture, an optional annealing step may be necessary to optimize blend morpohology and consequently OPV device performance.

The OPV device can for example be of any type known from the literature [see e.g. Waldauf et al., Appl. Phys. Lett., 2006, 89, 233517].

A first preferred OPV device according to the invention comprises:
a low work function electrode (for example a metal, such as aluminum), and a high work function electrode (for example ITO), one of which is transparent,
a layer (also referred to as “active layer”) comprising a hole transporting material and an electron transporting material, preferably selected from OSC materials, situated between the electrodes; the active layer can exist for example as a bilayer or two distinct layers or blend or mixture of p-type and n-type semiconductor, forming a bulk heterjunction (BHJ) (see for example Coakley, K. M. and McGehee, M. D. Chem. Mater., 2004, 16, 4533),
an optional conducting polymer layer, for example comprising a blend of PEDOT:PSS (poly(3,4-ethylenedioxythiophene):poly(styrenesulfonate)), situated between the active layer and the high work function electrode, to modify the work function of the high work function electrode to provide an ohmic contact for holes,
an optional coating (for example of LiF) on the side of the low workfunction electrode facing the active layer, to provide an ohmic contact for electrons.

A second preferred OPV device according to the invention is an inverted OPV device and comprises:
a low work function electrode (for example a metal, such as gold), and a high work function electrode (for example ITO), one of which is transparent,
a layer (also referred to as “active layer”) comprising a hole transporting material and an electron transporting material, preferably selected from OSC materials, situated between the electrodes; the active layer can exist for example as a bilayer or two distinct layers or blend or mixture of p-type and n-type semiconductor, forming a BHJ,
an optional conducting polymer layer, for example comprising a blend of PEDOT:PSS, situated between the active layer and the low work function electrode to provide an ohmic contact for electrons,
an optional coating (for example of TiOₓ) on the side of the high workfunction electrode facing the active layer, to provide an ohmic contact for holes.

In the OPV devices of the present invent invention the p-type and n-type semiconductor materials are preferably selected from the materials, like the p-type compound/fullerene systems, as described above. If the bilayer is a blend an optional annealing step may be necessary to optimize device performance.

The compound, formulation and layer of the present invention are also suitable for use in an OFET as the semiconducting channel. Accordingly, the invention also provides an OFET comprising a gate electrode, an insulating (or gate insulator) layer, a source electrode, a drain electrode and an organic semiconducting channel connecting the source and drain electrodes, wherein the organic semiconducting channel comprises a compound, formulation or organic semiconducting layer according to the present invention. Other features of the OFET are well known to those skilled in the art.

OFETs where an OSC material is arranged as a thin film between a gate dielectric and a drain and a source electrode, are generally known, and are described for example in U.S. Pat. No. 5,892,244, U.S. Pat. No. 5,998,804, U.S. Pat. No. 6,723,394 and in the references cited in the background section. Due to the advantages, like low cost production using the solubility properties of the compounds according to the invention and thus the processibility of large surfaces, preferred applications of these FETs are such as integrated circuitry, TFT displays and security applications.

The gate, source and drain electrodes and the insulating and semiconducting layer in the OFET device may be arranged in any sequence, provided that the source and drain electrode are separated from the gate electrode by the insulating layer, the gate electrode and the semiconductor layer both contact the insulating layer, and the source electrode and the drain electrode both contact the semiconducting layer.

An OFET device according to the present invention preferably comprises:
a source electrode,
a drain electrode,
a gate electrode,
a semiconducting layer,
one or more gate insulator layers,
optionally a substrate.

wherein the semiconductor layer preferably comprises a compound or formulation as described above and below.

The OFET device can be a top gate device or a bottom gate device. Suitable structures and manufacturing methods of an OFET device are known to the skilled in the art and are described in the literature, for example in US 2007/0102696 A1.

The gate insulator layer preferably comprises a fluoropolymer, like e.g. the commercially available Cytop 809M® or Cytop 107M® (from Asahi Glass).

Preferably the gate insulator layer is deposited, e.g. by spin-coating, doctor blading, wire bar coating, spray or dip coating or other known methods, from a formulation comprising an insulator material and one or more solvents with one or more fluoro atoms (fluorosolvents), preferably a perfluorosolvent. A suitable perfluorosolvent is e.g. FC75® (available from Acros, catalogue number 12380). Other suitable fluoropolymers and fluorosolvents are known in prior art, like for example the perfluoropolymers Teflon AF® 1600 or 2400 (from DuPont) or Fluoropel® (from Cytonix) or the perfluorosolvent FC 43® (Acros, No. 12377). Especially preferred are organic dielectric materials having a low permittivity (or dielectric contant) from 1.0 to 5.0, very preferably from 1.8 to 4.0 (“low k materials”), as disclosed for example in US 2007/0102696 A1 or U.S. Pat. No. 7,095,044.

In security applications, OFETs and other devices with semiconducting materials according to the present invention, like transistors or diodes, can be used for RFID tags or security markings to authenticate and prevent counterfeiting of documents of value like banknotes, credit cards or ID cards, national ID documents, licenses or any product with monetry value, like stamps, tickets, shares, cheques etc.

Alternatively, the materials according to the invention can be used in OLEDs, e.g. as the active display material in a flat panel display applications, or as backlight of a flat panel display like e.g. a liquid crystal display. Common OLEDs are realized using multilayer structures. An emission layer is generally sandwiched between one or more electron-transport and/or hole-transport layers. By applying an electric voltage electrons and holes as charge carriers move towards the emission layer where their recombination leads to the excitation and hence luminescence of the lumophor units contained in the emission layer. The inventive compounds, materials and films may be employed in one or more of the charge transport layers and/ or in the emission layer, corresponding to their electrical and/ or optical properties. Furthermore their use within the emission layer is especially advantageous, if the compounds, materials and films according to the invention show electroluminescent properties themselves or comprise electroluminescent groups or compounds. The selection, characterization as well as the processing of suitable monomeric, oligomeric and polymeric compounds or materials for the use in OLEDs is generally known by a person skilled in the art, see, e.g., Müller et al, Synth. Metals, 2000, 111-112, Alcala, J. Appl. Phys., 2000, 88, 7124-7128 and the literature cited therein.

According to another use, the materials according to this invention, especially those showing photoluminescent properties, may be employed as materials of light sources, e.g. in display devices, as described in EP 0 889 350 A1 or by C. Weder et al., Science, 1998, 279, 835-837.

A further aspect of the invention relates to both the oxidised and reduced form of the compounds according to this invention. Either loss or gain of electrons results in formation of a highly delocalised ionic form, which is of high conductivity. This can occur on exposure to common dopants. Suitable dopants and methods of doping are known to those skilled in the art, e.g. from EP 0 528 662, US 5,198,153 or WO 96/21659.

The doping process typically implies treatment of the semiconductor material with an oxidating or reducing agent in a redox reaction to form delocalised ionic centres in the material, with the corresponding counterions derived from the applied dopants. Suitable doping methods comprise for example exposure to a doping vapor in the atmospheric pressure or at a reduced pressure, electrochemical doping in a solution containing a dopant, bringing a dopant into contact with the semiconductor material to be thermally diffused, and ion-implantantion of the dopant into the semiconductor material.

When electrons are used as carriers, suitable dopants are for example halogens (e.g., I₂, Cl₂, Br₂, ICl, ICl₃, IBr and IF), Lewis acids (e.g., PF₅, AsF₅, SbF₅, BF₃, BCl₃, SbCl₅, BBr₃ and SO₃), protonic acids, organic acids, or amino acids (e.g., HF, HCl, HNO₃, H₂SO₄, HClO₄, FSO₃H and ClSO₃H), transition metal compounds (e.g., FeCl₃, FeOCl, Fe(ClO₄)₃, Fe(4-CH₃C₆H₄SO₃)₃, TiCl₄, ZrCl₄, HfCl₄, NbF₅, NbCl₅, TaCl₅, MoF₅, MoCl₅, WF₅, WCl₆, UF₆ and LnCl₃ (wherein Ln is a lanthanoid), anions (e.g., Cl⁻, Br⁻, I⁻, I₃⁻, HSO₄⁻, SO₄²⁻, NO₃⁻, ClO₄⁻, BF₄⁻, PF₆⁻, AsF₆⁻, SbF₆⁻, FeCl₄⁻, Fe(CN)₆³⁻, and anions of various sulfonic acids, such as aryl-SO₃⁻). When holes are used as carriers, examples of dopants are cations (e.g., H⁺, Li⁺, Na⁺, K⁺, Rb⁺and Cs⁺), alkali metals (e.g., Li, Na, K, Rb, and Cs), alkaline-earth metals (e.g., Ca, Sr, and Ba), O₂, XeOF₄, (NO₂⁺) (SbF₆⁻), (NO₂⁺) (SbCl₆⁻), (NO₂⁺) (BF₄⁻), AgClO₄, H₂IrCl₆, La(NO₃)₃.6H₂O, FSO₂OOSO₂F, Eu, acetylcholine, R₄N⁺, (R is an alkyl group), R₄P⁺ (R is an alkyl group), R₆As⁺ (R is an alkyl group), and R₃S⁺ (R is an alkyl group).

The conducting form of the compounds of the present invention can be used as an organic “metal” in applications including, but not limited to, charge injection layers and ITO planarising layers in OLED applications, films for flat panel displays and touch screens, antistatic films, printed conductive substrates, patterns or tracts in electronic applications such as printed circuit boards and condensers.

The compounds and formulations according to the present invention amy also be suitable for use in organic plasmon-emitting diodes (OPEDs), as described for example in Koller et al., Nat. Photonics, 2008, 2, 684.

According to another use, the materials according to the present invention can be used alone or together with other materials in or as alignment layers in LCD or OLED devices, as described for example in US 2003/0021913. The use of charge transport compounds according to the present invention can increase the electrical conductivity of the alignment layer. When used in an LCD, this increased electrical conductivity can reduce adverse residual dc effects in the switchable LCD cell and suppress image sticking or, for example in ferroelectric LCDs, reduce the residual charge produced by the switching of the spontaneous polarisation charge of the ferroelectric LCs. When used in an OLED device comprising a light emitting material provided onto the alignment layer, this increased electrical conductivity can enhance the electroluminescence of the light emitting material. The compounds or materials according to the present invention having mesogenic or liquid crystalline properties can form oriented anisotropic films as described above, which are especially useful as alignment layers to induce or enhance alignment in a liquid crystal medium provided onto said anisotropic film. The materials according to the present invention may also be combined with photoisomerisable compounds and/or chromophores for use in or as photoalignment layers, as described in US 2003/0021913.

According to another use the materials according to the present invention, especially their water-soluble derivatives (for example with polar or ionic side groups) or ionically doped forms, can be employed as chemical sensors or materials for detecting and discriminating DNA sequences. Such uses are described for example in L. Chen, D. W. McBranch, H. Wang, R. Helgeson, F. Wudl and D. G. Whitten, Proc. Natl. Acad. Sci. U.S.A., 1999, 96, 12287; D. Wang, X. Gong, P. S. Heeger, F. Rininsland, G. C. Bazan and A. J. Heeger, Proc. Natl. Acad. Sci. U.S.A., 2002, 99, 49; N. DiCesare, M. R. Pinot, K. S. Schanze and J. R. Lakowicz, Langmuir, 2002, 18, 7785; D. T. McQuade, A. E. Pullen, T. M. Swager, Chem. Rev., 2000, 100, 2537.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to or alternative to any invention presently claimed.

The invention will now be described in more detail by reference to the following examples, which are illustrative only and do not limit the scope of the invention.

### EXAMPLE 1

### 2,8-Difluoro-5,11-bis(allyldiisopropylsilylethynyl)anthradithiophene (8) (ADiPS-F-ADT)

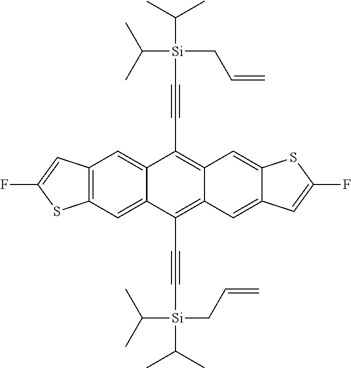 [SMILES: C=CC[Si](C#Cc1c2cc3cc(F)sc3cc2c(C#C[Si](CC=C)(C(C)C)C(C)C)c2cc3cc(F)sc3cc12)(C(C)C)C(C)C]

### Allyldiisopropyl(trimethylsilylethynyl)silane (3)

A solution of dichlorodiisopropylsilane (9.55 g, 97%, 50 mmol) in anhydrous THF (50 cm³) was cooled to −78° C. Allylmagnesium bromide solution (1.0 mol/L, 60 cm³) was added dropwise over the period of 1 hour to yield a thick white suspension. The suspension was stirred at −78° C. for 2 hours. The cooling bath was removed and the suspension was stirred without cooling for an additional 1.5 hours. Lithium trimethylsilylacetylide solution (1.0M in THF, prepared by reacting trimethylsilylacetylene with n-BuLi) was added at 23° C. rapidly. The previous suspension became a clear solution after the addition. The reaction mixture was stirred at 50° C. for 1 hour then stirred at 23° C. for 15 hours. The reaction mixture was concentrated in vacuo and a mixture of ice and 1N HCl was added. The organic phase was taken into diethyl ether (2×50 cm³), then dried over MgSO₄, and was concentrated in vacuo to yield a pale-yellow liquid. The crude product was purified by fractional distillation using a Vigeux column of ca. 15 cm under reduced pressure of 4 mBar to yield the product as a colourless liquid (9.37 g, 59%, calculated based on 84% purity) at 87-89° C. GCMS indicated that the purity of the liquid contained 84% of compound 3 with a molecular mass 252 g/mol. This liquid was directly used for the next step deprotection without further purification.

### Ethynylallyldiisopropylsilane (4)

To a solution of allyldiisopropyl(trimethylsilylethynyl)silane (3) (6.04 g, 20.09 mmol, based on 84% purity) in dichloromethane (20 cm³) and methanol (20 cm³) was added manually powdered potassium carbonate (5.8 g, 41.97 mmol). The reaction mixture was stirred at 23° C. for 1 hour before filtering through a silica pad. The filtrate was concentrated in vacuo to yield a pale yellow liquid. The crude product was purified by fractional distillation under reduced pressure to afford the product as a colourless liquid (3.47 g, 84%). ¹H-NMR (CDCl₃, 300 MHz): δ (ppm)=1.06 (m, 14H), 1.69 (dt, J1=8.0 Hz, J2=1.2 Hz, 2H), 2.39 (s, 1H), 4.87-5.00 (m, 2H), 5.79-5.94 (m, 1H). MS (m/z): 180 (M⁺).

### 2,8-Difluoro-5,11-bis(allyldiisopropylsilylethynyl)anthradithiophene (8) (ADiPS-F-ADT)

To a solution of ethynylallyldiisopropylsilane (4) (3.00 g, 16.64 mmol) in dioxane (30 cm³) was added 2.5M n-BuLi in hexanes (6.66 cm³, 16.65 mmol) dropwise at 0° C. over a period of 10 minutes. The cooling bath was removed and the reaction was stirred at 23° C. for 30 minutes to afford a colourless clear solution. 2,8-Difluoroanthradithiophene-5,11-dione (6) (1.95 g, 5.47 mmol)) was added in one portion to the lithium acetylide solution and the reaction mixture was stirred at 23° C. for 16 hours and then at 60° C. for an additional 1 hour before cooling to 23° C. A mixture of iced cold 5% HCl (14 cm³) was added. The organic layer was separated and washed with water whilst the aqueous layer was extracted with diethyl ether (20 cm³). The combined organic extracts were concentrated in vacuo. The crude product was purified by column chromatography on silica gel (eluent: dichloromethane:petroleum ether 40-60; 1:1) followed by recrystallisation from petroleum ether 80-100 to yield the product (7) as off-white needles (2.11 g, 55%). ¹H-NMR (CDCl₃, 300 MHz): δ (ppm)=1.03 (s, 14H), 1.68 (dt, J1=8.0 Hz, J2=1.2 Hz, 2H), 3.15 (t, caused by isomers, 1H), 4.80-4.93 (m, 2H), 5.72-5.87 (m, 1H), 6.77 (d, J=2.2 Hz, 1H), 8.39 (d, J=2.6 Hz, 1H), 8.45 (d, J=2.6 Hz, 1H).

Product (7) (2.11 g, 2.94 mmol) was dissolved in THF (20 cm³) and tin chloride solution in 2.5N HCl (8 cm³) was added under stirring. The reaction mixture was stirred at 23° C. vigorously for 30 minutes. Methanol (50 cm³) was added and the solid was collected by filtration. The solid was recrystallised from butanone-isopropanol (1:2) to yield product (8) as red crystals (1.94 g, 97%). M.p.:=202.9° C. (DSC). ¹H-NMR (CDCl₃, 300 MHz): δ (ppm)=1.29 (s, 14H), 1.95 (dt, J1=8.0 Hz, J2=1.2 Hz, 2H), 5.01-5.18 (m, 2H), 6.02-6.16 (m, 1H), 6.80 (d, J=2.4 Hz, 1H), 8.87 (s, 1H), 8.96 (s, 1H).

### EXAMPLE 2

### 2,8-Difluoro-5,11-bis(cyclohexyldimethylsilylethynyl)anthradithiophene (cHDMS-F-ADT)

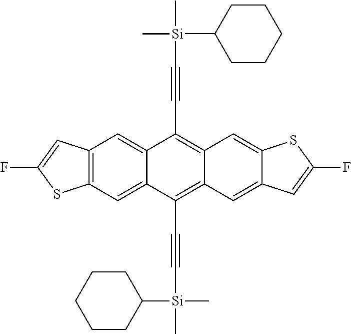 [SMILES: C[Si](C)(C#Cc1c2cc3cc(F)sc3cc2c(C#C[Si](C)(C)C2CCCCC2)c2cc3cc(F)sc3cc12)C1CCCCC1]

### Ethynylcyclohexyldimethylsilane

To a stirred yellow solution of ethynylmagnesium bromide (0.5M in THF, 67 cm³) at 20° C. was added cyclohexyldimethylchlorosilane (3.95 g) dropwise. The solution was stirred at 20° C. for 45 minutes and at 50° C. for an additional 15 minutes. The solvents of the reaction mixture were removed by evaporation in vacuo to afford thick yellow slurry. 3% HCl-ice mixture (50 cm³) was added in one portion and the mixture was stirred for 5 minutes. The organic part was taken into diethyl ether (2×20 cm³) and dried over magnesium sulfate. The ether solution was concentrated and the yellow oil residue was vacuum distilled at 130-135° C. (25 mBar) to afford the product as a colourless liquid (2.99 g, 80%). GCMS: 166 [M⁺]. ¹H-NMR (CDCl₃, 300 MHz): δ (ppm)=0.12 (s, 6H), 0.67 (m, 1H), 1.21 (m, 5H), 1.75 (m, 5H), 2.36 (s, 1H); ¹³C-NMR (CDCl₃, 75 MHz): δ (ppm)=−3.9, 25.3, 26.8, 27.0, 27.8, 88.8, 93.6.

### 2,8-Difluoro-5,11-bis(cyclohexyldimethylsilylethynyl)anthradithiophene (cHDMS-F-ADT)

To a solution of ethynylcyclohexyldimethylsilane (2.90 g, 98%, 17.17 mmol) in anhydrous dioxane (30 cm³) was added at 0° C. 2.5M n-BuLi in hexanes (6.9 cm³, 17.25 mmol) dropwise over 10 minutes. The cooling bath was removed and the suspension was stirred at 20° C. for an additional 30 minutes. 2,8-Difluoroanthradithiophene-5,11-dione (6) (2.04 g, 5.72 mmol) was added in one portion as solid and the mixture was stirred at 20° C. for 2 hours. The solution was heated in an oil-bath and stirred at 60° C. for an additional 2 hours then cooled to 0° C. with an ice-bath. Ice cold 1% HCl (ca. 50 cm³) as added quickly. The mixture was stirred for 5 minutes. The organic layer was separated and washed with water. The aqueous layer was extracted with diethyl ether once (20 cm³). The combined organic solution was dried of solvents by vacuum evaporation. The oily residue was then flash columned on silica gel (2:1 DCM/petroleum ether 40-60) to yield the diol intermediate (2.0 g). ¹H-NMR (CDCl₃, 300 MHz): δ (ppm)=0.11 (m, 6H), 0.69 (m, 1H), 1.17 (m, 5H), 1.68 (m, 5H), 3.33 (t, caused by isomers, 1H) , 6.78 (s, 1H), 8.36 (s, 1H), 8.42 (s, 1H).

The diol intermediate was dissolved in THF (20 cm³) and tin(II) chloride (2.20 g) solution in 2.5N HCl (8 cm) was added dropwise under stirring. The mixture was stirred at 20° C. vigorously for 30 minutes. Methanol (50 cm³) was added and the suspension was suction filtered to yield red crystals (2.00 g). The crystals were recrystallised from chloroform (50 cm³)-MEK (20 cm³) to yield cHDMS-F-ADT (1.64 g, 44% for two steps). M.p.: 197.6° C. (DSC). ¹H-NMR (CDCl₃, 300 MHz): δ (ppm)=0.39 (s, 6H), 0.96 (m, 1H), 1.37 (m, 5H), 1.90 (m, 3H), 1.98 (m, 2H), 6.81 (s, 1H), 8.83 (s, 1H), 8.92 (s, 1H).

### EXAMPLE 3

### 2,8-Difluoro-5,11-bis(tert-butyldimethylsilylethynyl)anthradithiophene (tBDMS-F-ADT)

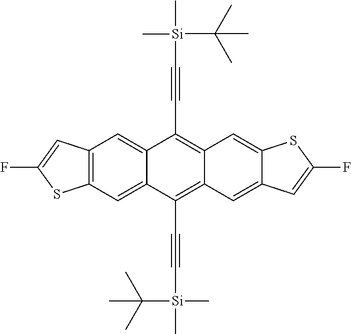 [SMILES: CC(C)(C)[Si](C)(C)C#Cc1c2cc3cc(F)sc3cc2c(C#C[Si](C)(C)C(C)(C)C)c2cc3cc(F)sc3cc12]

To a solution of (tert-butyldimethylsilyl)acetylene (2.10 g, 15 mmol)) in anhydrous dioxane (25 cm³) was added at 0° C. 2.5M n-BuLi in hexanes (6.0 cm³, 15.0 mmol) dropwise over 5 minutes. The cooling bath was removed and the suspension was stirred at 20° C. for an additional 30 minutes. 2,8-Difluoroanthradithiophene-5,11-dione (6) (1.78 g, 5.0 mmol) was added in one portion and the mixture was stirred at 20° C. for 3 hours. The suspension was heated in an oil-bath and stirred at 100° C. for an additional 1 hour, then cooled to 20° C. Ice cold 2% HCl (25 cm³) was added quickly and the mixture was stirred for ca. 5 minutes. The organic layer was separated and washed with water. The aqueous layer was extracted with diethyl ether once (20 cm³). The combined organic solution was dried of solvents by vacuum evaporation. The oily residue was flash columned on silica and eluted first with 1:2 DCM/petroleum ether 40-60 to yield the first isomer of the diol intermediate, which was recrystallised from petroleum ether 80-100 to yield orange crystals (1.95 g). The eluent was changed to DCM to wash the second isomer off the column as reddish thick oil.

The crystals of the first diol isomer was dissolved into THF (20 cm³) and SnCl₂ (1.90 g) solution in 2.5N HCl (6 cm³) was added and the deep red solution was stirred at 20° C. for 10 minutes to yield a red suspension. Methanol (ca. 50 cm³) was added and the suspension was suction filtered to yield a rosy red crystalline solid (1.82 g). The 2nd isomer crude solid was treated in the same way as the first isomer to yield another batch of red crystals (0.59 g). NMR spectra showed that both solid were of the same quality. The solids were combined and purified by flash chromatography on silica eluted with cyclohexane and follow by a recrystallisation from butanone-isopropanol mixture to yield pure tBDMS-F-ADT as red crystals (2.21 g, 80%). M.p.: 303° C. (DSC). ¹H-NMR (CDCl₃, 300 MHz): δ (ppm)=0.41 (s, 6H), 1.17 (s, 9H), 6.81 (s, 1H), 8.83 (s, 1H), 8.90 (s, 1H).

Additional examples (4-14) are also synthesise analogously and are summarised in Table 4.

TABLE 4
Examples of 2,8-difluoro-5,11-bis(silylethynyl)anthradithiophenes

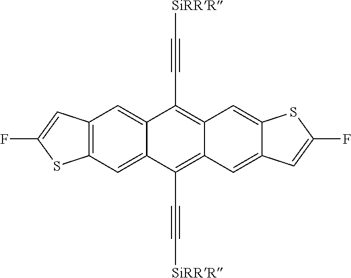

| | | | | Onset m.p. |
|---|---|---|---|---|
| Example | R | R′ | R″ | (° C.) |
| 1 | isopropyl | isopropyl | allyl | 198 |
| 2 | methyl | methyl | cyclohexyl | 183 |
| 3 | methyl | methyl | t-butyl | 303 |
| 4 | allyl | ethyl | ethyl | 176 |
| 5 | ethyl | ethyl | 2-butyl | 166 |
| 6 | isopropyl | isopropyl | phenyl | 175 |
| 7 | methyl | phenyl | vinyl | 226 |
| 8 | methyl | methyl | benzyl | 205 |
| 9 | ethyl | isopropyl | isopropyl | 220 |
| 10 | ethyl | ethyl | isopropyl | 193 |
| 11 | phenyl | phenyl | vinyl | 247 |
| 12 | ethyl | ethyl | cyclopentyl | 177 |
| 13 | ethyl | ethyl | cyclohexyl | 125 |
| 14 | ethyl | ethyl | t-butyl | 234 |

### EXAMPLE 4

### 2,8-Difluoro-5,11-bis(allyldiethylsilylethynyl)anthradithiophene

The pure product was obtained as red crystals after purification with flash chromatography on silica eluted with cyclohexane. The yield was 24%. Mp: 176° C. (onset, DSC). ¹H-NMR (CDCl₃, 300 MHz): δ (ppm)=0.93 (dq, J=8.0 Hz, 4H), 1.24 (t, J=8.1 Hz, 6H), 1.94 (d, J=8.0 Hz, 2H), 5.02-5.16 (m, 2H), 5.98-6.12 (m, 1H), 6.82 (d, J=2.5 Hz, 1H); 8.84 (s, 1H), 8.93 (s, 1H).

### EXAMPLE 5

### 2,8-Difluoro-5,11-bis(2-butyl diethylsilylethynyl)anthradithiophene

The pure product was obtained as red-orange crystals after purification with flash chromatography on silica eluted with cyclohexane. The yield was 62%. Mp: 166° C. (onset, DSC). ¹H-NMR (CDCl₃, 300 MHz): δ (ppm)=0.92 (m, 4H), 1.12 (t, J=7.3 Hz, 3H), 1.25 (t, J=8.5 Hz, 9H), 1.39-1.52 (m, 1H), 1.81-1.95 (m, 1H), 6.81 (d, J=2.5 Hz, 1H), 8.86 (s, 1H), 8.94 (s, 1H).

### EXAMPLE 6

### 2,8-Difluoro-5,11-bis(diisopropylphenylsilylethynyl)anthradithiophene

The pure product was obtained as red crystals after purification with flash chromatography on silica eluted with warm cyclohexane. The yield was 68%. The X-Ray crystal structure from a red prizm grown from cyclo-hexane was obtained. Mp: 175° C. (onset, DSC). ¹H-NMR (CDCl₃, 300 MHz): δ (ppm)=1.22 (d, J=7.3 Hz, 6H), 1.33 (d, J=7.3 Hz, 6H), 1.49-1.59 (m, 2H), 6.80 (s, 1H), 7.48 (m, 3H), 7.85 (m, 2H), 8.96 (s, 1H), 9.03 (s, 1H).

### EXAMPLE 7

### 2,8-Difluoro-5,11-bis(methylphenylvinylsilylethynyl)anthradithiophene

The pure product was obtained as red crystals after recrystallisation from chloroform 2-butanone mixture. The yield was 21%. Mp: 226° C. (onset, DSC). ¹H-NMR (CDCl₃, 300 MHz): δ (ppm)=0.79 (s, 3H), 6.17 (dm, J=19.9 Hz, 1H), 6.31 (dm, J=14.5 Hz, 1H), 6.51 (dd, J1=19.8 Hz, J2=14.5 Hz, 1H), 6.76 (s, 1H), 7.50 (m, 3H), 7.87 (m, 2H), 8.79 (m, 1H), 8.88 (m, 1H).

### EXAMPLE 8

### 2,8-Difluoro-5,11-bis(benzyldimethylsilylethynyl)anthradithiophene

The pure product was obtained as dark-red crystals after a purification by flash-chromatography on silica eluted with 3:1 cyclohexane-chloroform mixture, followed by a recrystallisation from 2-butanone. The yield was 34%. Mp: 205° C. (onset, DSC). ¹H-NMR (CDCl₃, 300 MHz): δ (ppm)=0.46 (t, 6H), 2.46 (s, 2H), 6.80 (d, J=2.6 Hz, 1H), 7.19-7.36 (m, 5H), 8.67 (s, 1H), 8.73 (s, 1H).

### EXAMPLE 9

### 2,8-Difluoro-5,11-bis(ethyldiisopropylsilylethynyl)anthradithiophene

The pure product was obtained as orange-red crystals in 47% yield after a purification by flash-chromatography on silica eluted with cyclohexane, followed by a recrystallisation from cyclohexane-ethanol mixture. Mp: 220° C. (onset, DSC). ¹H-NMR (CDCl₃, 300 MHz): δ (ppm)=0.92 (q, J=7.9 Hz, 2H), 1.28 (m, 17H), 6.80 (d, J=2.5 Hz, 1H), 8.88 (s, 1H), 8.95 (s, 1H).

### EXAMPLE 10

### 2,8-Difluoro-5,11-bis(diethylisopropylsilylethynyl)anthradithiophene

The pure product was obtained as red crystals in 65% yield after a purification by flash-chromatography on silica eluted with petroleum ether (40-60° C)-dichloromethane 10:1 mixture, followed by a recrystallisation from 2-butanone-ethanol. Mp: 193° C. (onset, DSC). ¹H-NMR (CDCl₃, 300 MHz): δ (ppm)=0.81-0.90 (m, 4H), 1.19 (t, J=7.8 Hz, 13H), 6.76 (d, J=2.54 Hz, 1H), 8.82 (s, 1H), 8.89 (s, 1H).

### EXAMPLE 11

### 2,8-Difluoro-5,11-bis(diphenylvinylsilylethynyl)anthradithiophene

The pure product was obtained as red crystals in 19% yield after recrystallisation from chloroform and 2-butanone mixture. Mp: 247° C. (DSC). ¹H-NMR (CDCl₃, 300 MHz): δ (ppm)=6.21 (dm, J=19.9 Hz, 1H), 6.43 (dm, J=14.5 Hz, 1H), 6.70 (dd, J1=19.9 Hz, J2=14.4 Hz, 1H), 6.72 (d, J=1.8 Hz, 1H), 7.52 (m, 6H), 7.88 (m, 4H), 8.82 (s, 1H), 8.90 (s, 1H).

### EXAMPLE 12

### 2,8-Difluoro-5,11-bis(cyclopentyldiethylsilylethynyl)anthradithiophene

The pure product was obtained as red plates in 34% yield after a purification by flash-chromatography on silica (cyclohexane eluent) and recrystallisation from cyclohexane. Mp: 177° C. (onset, DSC). 1H-NMR (CDCl₃, 300 MHz): δ (ppm)=0.91 (m, 4H), 1.23 (t, J=7.8 Hz, 6H), 1.30 (m, 1H), 1.70 (m, 6H), 2.00 (m, 2H), 6.80 (d, J=2.5 Hz, 1H), 8.85 (s, 1H), 8.93 (s, 1H).

### EXAMPLE 13

### 2,8-Difluoro-5,11-bis(cyclohexyldiethylsilylethynyl)anthradithiophene

The pure product was obtained as red plates in 67% yield after a purification by flash-chromatography on silica (10:1 light petroleum ether-DCM eluent) and a recrystallisation from 2-butanone. Mp: 125° C. (onset, DSC). ¹H-NMR (CDCl₃, 300 MHz): δ (ppm)=0.81-0.95 (m, 4H), 1.06 (m, 1H), 1.23 (t, J=7.8 Hz, 6H), 1.34 (m, 3H), 1.46 (m, 2H), 1.84 (m, 3H), 1.99 (d, J=13 Hz, 2H), 6.80 (d, J=2.5 Hz, 1H), 8.87 (s, 1H), 8.95 (s, 1H).

### EXAMPLE 14

### 2,8-Difluoro-5,11-bis(tert-butyldiethylsilylethynyl)anthradithiophene

The pure product was obtained as red needles in 76% yield after a purification by flash-chromatography on silica (cyclohexane eluent) and a recrystallisation from 2-butanone-ethanol. Mp: 234° C. (onset, DSC). ¹H-NMR (CDCl₃, 300 MHz): δ (ppm)=0.92 (m, 4H), 1.19 (s, 9H), 1.29 (t, J=7.9 Hz, 6H), 6.80 (d, J=2.5 Hz, 1H), 8.89 (s, 1H), 8.95 (s, 1H).

### EXAMPLE 15

### 5,11-Bis(cyclohexyldimethylsilylethynyl)anthradithiophene (cHDMS-H-ADT)

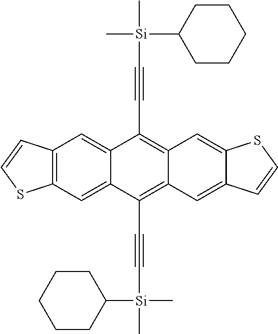 [SMILES: C[Si](C)(C#Cc1c2cc3ccsc3cc2c(C#C[Si](C)(C)C2CCCCC2)c2cc3ccsc3cc12)C1CCCCC1]

To a solution of ethynylcyclohexyldimethylsilane (0.732 g, 4.401 mmol) in dioxane (10 cm³) at 0° C. under nitrogen atmosphere was added n-BuLi (1.75 cm³, 2.5M in hexanes, 4.375 mmol) dropwise over 30 minutes. The solution was stirred at room temperature for 60 minutes. Anthradithiophene-5,11-dione (0.470 g, 1.467 mmol) was added in one portion as a solid and the mixture was heated at 50° C. for 1 hour. The resulting reaction mixture was stirred at 20° C. for 18 hours. A solution of SnCl₂ (1.113 g) in water (6 cm³) and 35% HCl (0.5 cm³) was added portion wise to the reaction mixture, which was stirred for an additional 40 minutes in the dark. The reaction mixture poured into methanol (100 cm³) and the precipitate was removed by filtration. The filtrate was concentrated in vacuo and and purified by column chromatography on silica gel (eluent: 1:1 diethyl ether:petroleum ether 40-60). The resulting residue was triturated with methanol and the precipitate was filtered off, washed with methanol, and dried under vacuum to give a dark red solid. Recrystallisation twice from MEK yielded the product (0.430 g, 47%) as dark-red needles. M.p.: 208° C. (DSC). ¹H-NMR (CDCl₃, 300 MHz): δ (ppm)=0.41 (s, 12H, 4CH₃) 0.92-1.03 (m, 2H, CH₂), 1.30-1.50 (bm, 10H, CH₂), 1.75-1.90 (bm, 6H, CH₂), 2.00-2.10 (bd, 4H, CH₂), 7.45-7.47 (d, J=5.75 Hz 2H, ArH), 7.55-7.57 (dd, J=5.70 Hz, 2H, ArH), 9.10 (s, 2H, ArH), 9.16 (s, 2H, ArH).

### EXAMPLE 16

### 2,8-Dimethyl-5,11-bis(tert-butyldimethylsilylethynyl)anthradithiophene (tBDMS-Me-ADT)

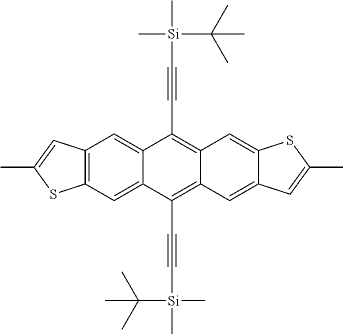

To a solution of (tert-butyldimethylsilyl)acetylene (1.812 g, 12.915 mmol) in dioxane (30 cm³) at 0° C. under nitrogen atmosphere was added n-BuLi (5.15 cm³, 2.5M in hexanes, 12.875 mmol) dropwise over 30 minutes. The solution was stirred at room temperature for 60 minutes. 2,8-Dimethylanthradithiophene-5,11-dione (1.500 g, 4.305 mmol) was added in one portion as a solid and the mixture was heated at 50° C. for 1 hour. The resulting reaction mixture was stirred at 20° C. for 17 hours. A solution of SnCl₂ (3.265 g) in water (18 cm³) and 35% HCl (1.5 cm³) was added portion wise to the reaction mixture, which was stirred for an additional 40 minutes in the dark. The reaction mixture poured into methanol (250 cm³) and the precipitate was removed by filtration. The filtrate was concentrated in vacuo and and purified by column chromatography on silica gel (eluent: cyclohexane). The resulting residue was triturated with methanol and the precipitate was filtered off, washed with methanol, and dried under vacuum to give a purple solid. Recrystallisation from MEK yielded the product (1.900 g, 74%) as purple needles. M.p.: 240° C. (DSC). ¹H-NMR (CDCl₃, 300 MHz): δ (ppm)=0.41 (s, 12H, CH₃) 1.18 (s, 18H, CH₃), 2.64 (s, 6H, CH₃), 7.08 (s, 2H, ArH), 8.86 (s, 2H, ArH), 8.97 (s, 2H, ArH).

### EXAMPLE 17

### Transistor Fabrication and Measurement

Top-gate thin-film organic field-effect transistors (OFETs) were fabricated on glass substrates with photolithographically defined Au source-drain electrodes. A solution (0.5-2.0 wt. %) of the compound example was spin-coated or drop-cast ontop. Next a fluoropolymer dielectric material (D139) was spin-coated ontop. Finally a photolithographically defined Au gate electrode was deposited. The electrical characterization of the transistor devices was carried out in ambient air atmosphere using computer controlled Agilent 4155C Semiconductor Parameter Analyser. Charge carrier mobility in the saturation regime (μₛₐₜ) was calculated for the compound and the results are summarized in Table 5. Field-effect mobility was calculated in the saturation regime (V_{d}>(V_{g}−V₀)) using equation (1):

$${( \frac{d {I}_{d}^{sat}}{d {V}_{g}} )}_{{V}_{d}} = \frac{W {C}_{i}}{L} {μ}^{sat} ( {V}_{g} - {V}_{0} ) \qquad ( 1 )$$

where W is the channel width, L the channel length, Cᵢ the capacitance of insulating layer, V_{g} the gate voltage, V₀ the turn-on voltage, and μₛₐₜ is the charge carrier mobility in the saturation regime. Turn-on voltage (V₀) was determined as the onset of source-drain current.

TABLE 5
Mobilties (μₛₐₜ) for compound examples in top-gate OFETs.

| | Mobility |
|---|---|
| Example | (μₛₐₜ)/cm²/Vs |
| 1 | 0.5 |
| 2 | 0.6 |
| 3 | 4 × 10⁻³ |
| 4 | 1.0 |
| 5 | 0.5 |
| 7 | 0.9 |
| 8 | 0.7 |
| 9 | 0.6 |
| 10 | 0.33 |
| 11 | 0.15 |
| 12 | 3 × 10⁻⁵ |
| 14 | 0.5 |
| 15 | 0.4 |
| 16 | 0.06 |

1. Compounds of formula I 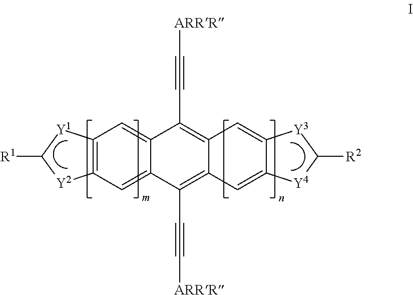
wherein the individual groups have the following meanings
one of Y¹ and Y² is —CH═ or ═CH— and the other is —X—,
one of Y³ and Y⁴ is —CH═ or ═CH— and the other is —X—,
X is —O—, —S—, —Se— or —NR^{x}—,
A is C or Si,
R¹ and R² independently of each other denote H, F, Cl, Br, I, straight chain, branched or cyclic alkyl with 1 to 20 C-atoms, which is unsubstituted or substituted by one or more groups L, and wherein one or more non-adjacent CH₂ groups are optionally replaced, in each case independently from one another, by —O—, —S—, —NR⁰—, —SiR⁰R⁰⁰—, —CY⁰═CY⁰⁰— or —C≡C— in such a manner that O and/or S atoms are not linked directly to one another, or denote aryl or heteroaryl with 4 to 20 ring atoms which is unsubstituted or substituted by one or more groups L,
R, R′, R″ are identical or different groups selected from the group consisting of H, a straight-chain, branched or cyclic alkyl or alkoxy group having 1 to 20 C atoms, a straight-chain, branched or cyclic alkenyl group having 2 to 20 C atoms, a straight-chain, branched or cyclic alkynyl group having 2 to 20 C atoms, a straight-chain, branched or cyclic alkylcarbonyl group having 2 to 20 C atoms, an aryl or heteroaryl group having 4 to 20 ring atoms, an arylalkyl or heteroarylalkyl group having 4 to 20 ring atoms, an aryloxy or heteroaryloxy group having 4 to 20 ring atoms, or an arylalkyloxy or heteroarylalkyloxy group having 4 to 20 ring atoms, wherein all the aforementioned groups are optionally substituted with one or more groups L,
L is selected from P-Sp-, F, Cl, Br, I, —OH, —CN, —NO₂, —NCO, —NCS, —OCN, —SCN, —C(═O)NR⁰R⁰⁰, —C(═O)X⁰, —C(═O)R⁰, —NR⁰R⁰⁰, C(═O)OH, optionally substituted aryl or heteroaryl having 4 to 20 ring atoms, or straight chain, branched or cyclic alkyl with 1 to 20, preferably 1 to 12 C atoms wherein one or more non-adjacent CH₂ groups are optionally replaced, in each case independently from one another, by —O—, —S—, —NR⁰—, —SiR⁰R⁰⁰—, —CY⁰═CY⁰⁰— or —C≡C— in such a manner that O and/or S atoms are not linked directly to one another and which is unsubstituted or substituted with one or more F or Cl atoms or OH groups,
P is a polymerisable group,
Sp is a spacer group or a single bond,
X⁰ is halogen,
R^{x} has one of the meanings given for R¹,
R⁰ and R⁰⁰ independently of each other denote H or alkyl with 1 to 20 C-atoms,
Y⁰ and Y⁰⁰ independently of each other denote H, F, Cl or CN,
m is 1 or 2,
n is 1 or 2,
wherein in at least one group ARR′R″ at least two of the substituents R, R′ and R″ are not identical.

2. Compounds according to claim 1, wherein X is S.

3. Compounds according to claim 1, wherein n=m=1.

4. Compounds according to claim 1, characterized in that they are a mixture of isomers, wherein in the first isomer Y¹═Y³ and Y²═Y⁴, and in the second isomer Y¹═Y⁴ and Y²═Y³.

5. Compounds according to claim 1, characterized in that, R, R′ and R″ are each independently selected from optionally substituted and straight-chain, branched or cyclic alkyl or alkoxy having 1 to 10 C atoms, which is for example methyl, ethyl, n-propyl, isopropyl, cyclopropyl, 2,3-dimethylcyclopropyl, 2,2,3,3-tetramethylcyclopropyl, cyclobutyl, cyclopentyl, methoxy or ethoxy, optionally substituted and straight-chain, branched or cyclic alkenyl, alkynyl or alkylcarbonyl having 2 to 12 C atoms, which is for example allyl, isopropenyl, 2-but-1-enyl, cis-2-but-2-enyl, 3-but-1-enyl, propynyl or acetyl, optionally substituted aryl, heteroaryl, arylalkyl or heteroarylalkyl, aryloxy or heteroaryloxy having 5 to 10 ring atoms, which is for example phenyl, p-tolyl, benzyl, 2-furanyl, 2-thienyl, 2-selenophenyl, N-methylpyrrol-2-yl or phenoxy.

6. Compounds according to claim 1, characterized in that R¹ and R² are selected from the group consisting of H, F, Cl, Br, I, —CN, and straight chain, branched or cyclic alkyl, alkoxy, thioalkyl, alkenyl, alkynyl, alkylcarbonyl, alkoxycarbonyl, alkylcarbonyloxy, alkylcarbonylamido, alkylamidocarbonyl or alkoxycarbonyloxy with 1 to 20, preferably 1 to 12 C atoms which is unsubstituted or substituted with one or more F or Cl atoms or OH groups or perfluorinated.

7. Compounds according to claim 1, characterized in that R¹ and R² are selected from the group consisting of furan, thiophene, selenophene, N-pyrrole, pyrimidine, thiazole, thiadiazole, oxazole, oxadiazole, selenazole, bi-, tri- or tetracyclic groups containing one or more of the aforementioned rings and optionally containing one or more benzene rings, wherein the individual rings are connected by single bonds or fused with each other, thieno[3,2-b]thiophene, dithieno[3,2-b:2′,3′-d]thiophene, selenopheno[3,2-b]selenophene-2,5-diyl, selenopheno[2,3-b]selenophene-2,5-diyl, selenopheno[3,2-b]thiophene-2,5-diyl, selenopheno[2,3-b]thiophene-2,5-diyl, benzo[1,2-b:4,5-b′]dithiophene-2,6-diyl, 2,2-dithiophene, 2,2-diselenophene, dithieno[3,2-b:2′,3′-d]silole-5,5-diyl, 4H-cyclopenta[2,1-b:3,4-b′]dithiophene-2,6-diyl, benzo[b]thiophene, benzo[b]selenophene, benzooxazole, benzothiazole, benzoselenazole, wherein all the aforementioned groups are unsubstituted, or substituted with one or more groups L as defined in claim 1.

8. Compounds according to claim 1, characterized in that they are selected from the following formulae 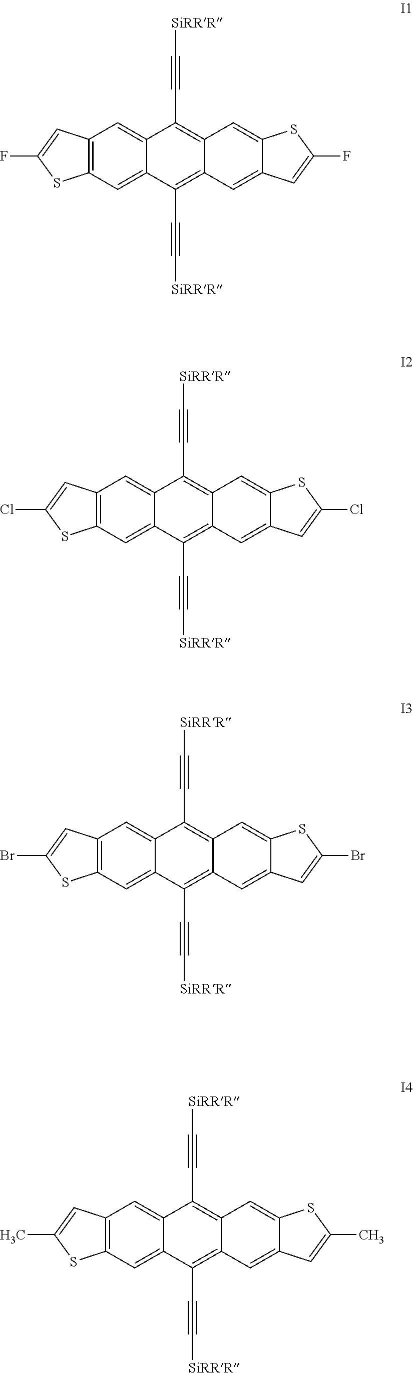 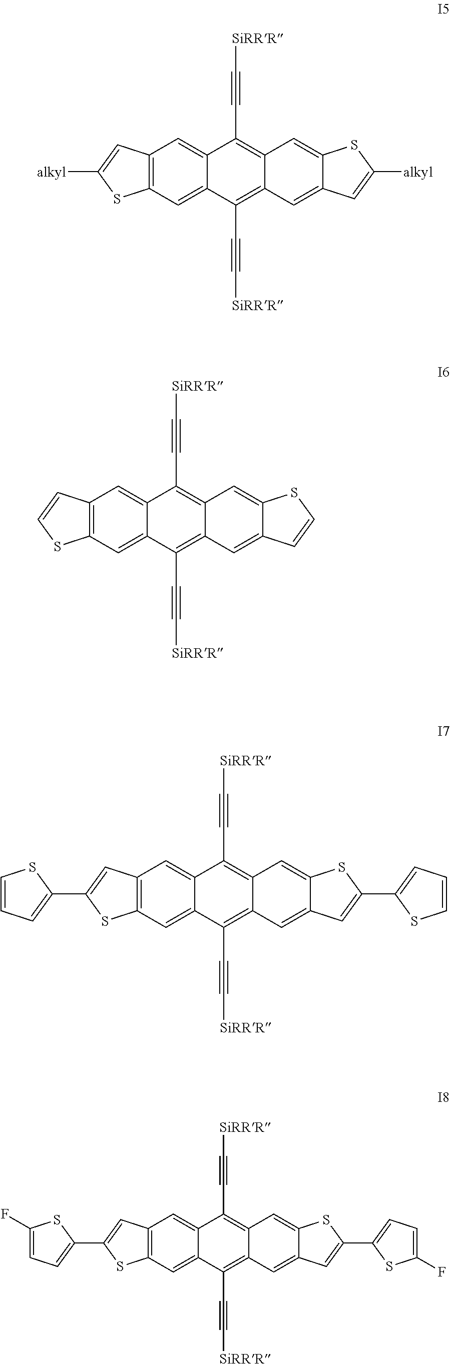
wherein R, R′ and R″ are as defined in claim 1 and “alkyl” denotes alkyl with 2, 3 or 4 C atoms.

9. Formulation comprising one or more compounds according to claim 1 and one or more organic solvents.

10. Organic semiconducting formulation comprising one or more compounds according to claim 1, one or more organic binders or precursors thereof, having a permittivity ε at 1,000 Hz of 3.3 or less, and optionally one or more solvents.

11. Use of compounds and formulations according to claim 1 as charge transport, semiconducting, electrically conducting, photoconducting or light emitting material in an optical, electrooptical, electronic, electroluminescent or photoluminescent components or devices.

12. Charge transport, semiconducting, electrically conducting, photoconducting or light emitting material or component comprising one or more compounds or formulations according to claim 1.

13. Optical, electrooptical, electronic, electroluminescent or photoluminescent component or device comprising one or more compounds, formulations, materials or components according to claim 1.

14. Component or device according to claim 13, characterized in that it is selected from the group consisting of organic field effect transistors (OFET), thin film transistors (TFT), integrated circuits (IC), logic circuits, capacitors, radio frequency identification (RFID) tags, devices or components, organic light emitting diodes (OLED), organic light emitting transistors (OLET), flat panel displays, backlights of displays, organic photovoltaic devices (OPV), solar cells, laser diodes, photoconductors, photodetectors, electrophotographic devices, electrophotographic recording devices, organic memory devices, sensor devices, charge injection layers, charge transport layers or interlayers in polymer light emitting diodes (PLEDs), organic plasmon-emitting diodes (OPEDs), Schottky diodes, planarising layers, antistatic films, polymer electrolyte membranes (PEM), conducting substrates, conducting patterns, electrode materials in batteries, alignment layers, biosensors, biochips, security markings, security devices, and components or devices for detecting and discriminating DNA sequences.

15. Method of preparing a compound according to claim 1, comprising the steps of:
a) Treating a dichlorosilane of the formula SiCl₂R₂ with a solution of R′MgBr, wherein R and R′ are as defined in formula I, for example R is a first alkyl group and R′ is an alkenyl group or a second alkyl group that is different from the first alkyl group, to yield a chlorosilane of the formula SiClR₂R′,
b) reacting the chlorosilane SiClR₂R′ from step a) with Li—C≡C—SiR⁰₃, wherein R⁰ is alkyl, for example methyl, to yield the corresponding protected silane of the formula R⁰₃Si—C≡C—SiR₂R′,
c) deprotecting the protected silane R⁰₃Si—C≡C—SiR₂R′, for example by treatment with potassium carbonate, to afford the unprotected silane of the formula H—C≡C—SiR₂R′,
b2) alternatively to steps b) and c), treating the chlorosilane SiClR₂R′ from step a) with ethynylmagnesium halide or lithium acetylide to afford the unprotected silane H—C≡C—SiR₂R′ directly.
d) lithiating the silane H—C≡C—SiR₂R′ from step c) or b2), for example with n-butyllithium, to provide the lithium silylacetylide of the formula Li—C≡C—SiR₂R′,
e) reacting the lithium silylacetylide Li—C≡C—SiR₂R′ from step d) with dithienoanthraquinone, which is optionally substituted in 2- and/or 8-position by R¹ and/or R² as defined in formula I, to yield the corresponding diol,
f) reacting the diol from step e) with a reducing reagent, for example SnCl₂, under acidic conditions to afford the anthra[2,3-b:7,6-b′]dithiophene, which is substituted by —C≡C—SiR₂R′ groups in 5- and 11-position and optionally substituted by R¹ and/or R² in 2- and/or 8-position.

16. Method of preparing a compound according to claim 1, comprising the following steps:
a) Reacting 2,3-Thiophenedicarboxaldehyde diacetal with alkyllithium, LDA or another lithiation reagent, and then reacting the resulting compound with a halogenation agent including but not limited to carbon tetrachloride, 1,2-dichloroethane, carbon tetrabromide, 1,2-dibromotetrachloroethane, 1,2-dibromoethane, 1-iodoperfluorohexane, iodinechloride, elemental iodine, to afford the 5-halogenated 2,3-thiophenedicarboxaldehyde diacetal,
b) deprotecting the 5-halogenated 2,3-thiophenedicarboxaldehyde diacetal from step a) under acidic conditions to the corresponding dialdehyde, which is then condensed with a cyclic 1,4-diketone, such as 1,4-cyclohexadione, 1,4-dihydroxy-naphthalene or its higher analogues, to yield the quinone of the dihalogenated acenodithiophene,
c) treating the quinone of the dihalogenated acenodithiophene from step b) with a lithium silylacetylide of the formula Li—C≡C—SiR₂R′, which is for example obtainable by a process as described above, and wherein R and R′ are as defined in formula I, for example R is a first alkyl group and R′ is an alkenyl group or a second alkyl group that is different from the first alkyl group, followed by a hydrolysis, for example with diluted HCl, to yield the dihalogenated diol intermediate,
d) cross-coupling the dihalogenated diol intermediate from step c) with a corresponding heteroaryl boronic acid, boronic ester, stannane, zinc halide or magnesium halide, in the presence of a nickel or palladium complex as catalyst, to yield the heteroaryl extended diol,
e) reacting the heteroaryl extended diol from step d) with a reducing agent, for example SnCl₂, under acidic conditions to afford the 2,8-diheteroaryl-anthra[2,3-b:7,6-b′]dithiophene which is substituted by —C≡C—SiR₂R′ groups in 5 and 11-position, or
b2) alternatively to steps b)-e), reacting the 5-halogenated 2,3-thiophenedicarboxaldehyde diacetal obtained by step a) in a cross-coupling reaction with a corresponding heteroaryl boronic acid, boronic ester, stannane, zinc halide or magnesium halide, in the presence of a nickel or palladium complex as catalyst, deprotecting the resulting product and condensing with a cyclic 1,4-diketone as described in step b), treating the resulting product with the lithium silylacetylide of the formula Li—C≡C—SiR₂R′ followed by hydrolysis as described in step c), and aromatising the resulting 2,8-diheteroaryl extended diol by reacting it with a reducing agent as described in step e), to afford the 2,8-diheteroaryl-anthra[2,3-b:7,6-b′]dithiophene which is substituted by —C≡C—SiR₂R′ groups in 5 and 11-position.
